(19) United States
(12) Patent Application Publication
(10) Pub. No.: US 2011/0169171 A1
(43) Pub. Date: Jul. 14, 2011

(54) Dual Interconnection in Stacked Memory and Controller Module

(75) Inventor: Phil P. Marcoux, Mountain View, CA (US)

(73) Assignee: WAFER-LEVEL PACKAGING PORTFOLIO LLC, Cupertino, CA (US)

(21) Appl. No.: 13/051,917

(22) Filed: Mar. 18, 2011

Related U.S. Application Data
(62) Division of application No. 12/431,569, filed on Apr. 28, 2009.

(51) Int. Cl. H01L 23/48

(52) U.S. Cl. 257/774; 257/E23.011

(57) ABSTRACT

A chip package transmitting slow speed signals via edge connectors and high speed signals by means of through-silicon-vias. The edge connectors are formed in recesses formed in the sidewalls of the package.

This application incorporates by reference U.S. Pat. No. 5,910,687 to Chen, et al., U.S. Pat. No. 5,505,816 to Barnes, et al., U.S. Pat. No. 5,656,547 to Richards, et al., U.S. Pat. No. 6,911,392 to Bieck, et al., and “3-D Through-Silicon Vias Become a Reality”, by Jan Vardaman, Semiconductor International, No. 6, Jun. 1, 2007.

### BACKGROUND OF THE INVENTION

1. Field of the Invention

The present invention relates generally to the field of semiconductor device manufacturing, and more particularly to an improved dual structure and method of interconnection for a multichip electronic circuit, such as a memory module.

2. Description of the Background Art

A semiconductor integrated circuit (IC) chip, also called a die, is typically formed in a polygonal shape comprising an active surface, also known as the front side or top side of the chip, a rear surface or rear side parallel to the active surface, but facing in the opposite direction, and edges extending between the active surface and the rear surface. The active surface has a plurality of I/O contact terminals (die terminals) disposed thereupon. The surface area of the active surface and the rear surface are usually equal, or nearly equal, and is greater than the surface area of the edge regions around the periphery of the chip, variously referred to herein as “edges” or “sidewalls”.

An IC chip can be mechanically attached or “mounted” to a substrate or circuit board, or a surface of an adjacent chip in a stack, from either the active surface (face-down orientation) or the rear surface (face-up orientation). In the face-down orientation, the active surface of the IC chip faces the substrate, and electrical connections to the die terminals are made through suitably aligned, matching terminals on the substrate, by conductive bumps through a process known as “flip chip” technology, or by ultrasonic or thermosonic bonding without solder bumps.

In the face-up orientation, the active surface of an IC chip is exposed, and electrical connections to die terminals on the exposed chip surface are conventionally made by wire bonds.

Multichip circuits, such as single in-line memory module (SIMM), dual in-line memory module (DIMM), and small outline dual in-line memory module (SO-DIMM) memory modules widely used in computers, include horizontally mounted memory chips or dice which are disposed adjacent to each other on the surface of a circuit board. A conventional DIMM 100 wherein a plurality of four memory chips 120 are placed horizontally on a board 140, is illustrated in FIG. 1. A multichip circuit is by definition distributed among a plurality of chips and accordingly, includes interconnecting wires and/or conductive traces between the chips and also external connections, which are conventionally routed along the surface of the board.

Conventional construction of multichip circuits has speed, cost, and reliability limitations. Interconnecting traces (also known as wires) along a printed circuit board between two IC chips, and/or along the surface of an IC chip, including wire bonds from a chip to the board, introduce signal transmission delay related to the length of the signal path. As computer operating and memory access speeds increase, such as with the DDR3, DDR4, GDDR4, and XDR interface technologies known in the art, transmission delay in the extended signal paths between horizontally mounted chips becomes a significant factor in limiting the overall speed of operation of a multichip circuit. The delay may result from a variety of factors. The longer a circuit trace or signal path, the greater the capacitive load, increasing the time required to charge or discharge the signal path in digital signal transmission. Similarly, at high operating frequency the series inductance of the signal path can affect signal rise time, thereby again, limiting the clock speed of a digital signal. This conventional memory card architecture not only fosters signal degradation, but component degradation as well. Because of a disparity in thermal expansion between silicon chips and the circuit boards on which silicon chips are typically mounted, thermal cycling failure plays an important role in reducing the operating life of a multichip module having horizontally mounted chips (i.e., wherein one of the chip's large surface areas is mounted against the circuit board).

Wire bonding used in conventional multichip circuits also has a cost issue. Gold wires now account for a significant portion of packaging cost.

A known technique to reduce such delay and thereby improve operating speed, and also to improve reliability, is to stack the chips on top of each other, in order to reduce the length of signal paths, and reduce thermal expansion-related problems. This is also a way to reduce wire cost, as wire bonds require loops and their elimination shrinks the length of connectors, even if the cross-sectional area of the connectors remains approximately the same. One known form of interconnection and stacked mounting of chips, referred to as ChipScale™ edge wrap, is disclosed by Chen, et al. (U.S. Pat. No. 5,910,687) and Richards, et al. (U.S. Pat. No. 5,656,547), both of which are incorporated by reference in their entirety herein. ChipScale™ edge wrap involves electrically connecting a die terminal on the front surface of an IC chip to a contact terminal on the rear of the chip, by conductive material such as wires, signal traces, etc. A portion of the ChipScale™ edge wrap is routed along the edge (sidewall) of the IC chip. The portion of the wire that passes around the edge of the chip, and which has contact areas or portions also on the top and bottom surfaces of the chip, is referred to as an edge wrap connector (EWC). ChipScale™ EWCs have been used to electrically interconnect suitably aligned terminals at the front and rear surfaces of adjacent chips in a stack of IC chips, by flip chip technology and similar methods. However, serpentine signal paths that include EWCs coupled with circuit traces on the surface of a chip do not provide the shortest circuit path, and delay between some critical circuit portions in a stacked multichip circuit.

Another known technique to reduce wiring delay is to stack the chips and interconnect them using through-silicon vias (TSVs) as described, for example, in Jan Vardaman, “3-D Through-Silicon Vias Become a Reality”, Semiconductor International, No. 6, Jun. 1, 2007, and in Bieck, et al. (U.S. Pat. No. 6,911,392), both of which are incorporated by reference herein. A TSV is a generally cylindrical, or slightly conical, region filled with conductive material, extending from the circuit side (active surface) of a chip to its back side (also referred to as its “rear surface”), and electrically connecting a die terminal on the active surface to a contact terminal on the rear surface. In a stack of IC chips, the die terminals of an IC are electrically connected through the rear contact terminals of TSVs to appropriately aligned terminals on an adjacent chip, either by cold formed (pressure formed, extruded) regions of the via metal or by small solder bumps at the back, using flip chip technology and similar methods. Prudent architecture using TSVs can significantly reduce the length of a signal path in a stack of IC chips. TSVs, however, take up valuable “real estate” within the active circuit area of a chip. This is particularly true in applications wherein a signal path requires a large cross-sectional area to reduce impedance below a predetermined threshold, such as for significant peak current carrying capability of power or ground signals. TSVs have a further recently discovered disadvantage that crystal structure defects can develop within a chip in the circuit area near closely spaced TSVs, which can reduce reliability.

A need exists, therefore, for improved interconnection structures and methods in a multichip circuit module.

### SUMMARY OF INVENTION

This invention provides a dual structure and method of interconnection between I/O contact terminals on the circuit (active, top) side of an integrated circuit chip and contact surfaces on the rear of the chip, including both through-silicon vias (TSVs) and edge connectors (ECs) on the same chip. The method includes partitioning the I/O signals of a chip, which are connected to respective terminals, into a first group of slow-speed signals, and a second group of high-speed signals, and connecting the first group by ECs and the second group by TSVs, to the rear contact surfaces, for interconnections between chips in a stack of chips, and for interconnections between a chip mounted face-up on a substrate, and traces on the substrate. In one embodiment, the first group of signals includes power and ground. In another embodiment, the first group further includes chip select signals, and other signals that pass through some of the chips in a stack.

In yet another embodiment, the invention provides a dual structure of interconnections in a stack of chips that uses less space in the circuit area of the chips, and thereby provides lower cost and better high-speed performance than offered by exclusive use of either ECs or TSVs alone.

In still another embodiment, the invention provides a dual structure of interconnections in a stacked multichip memory module wherein the chips have a common circuit layout rather than a plurality of custom layouts.

In a still further embodiment, the invention provides a dual structure of interconnections in a stack of memory chips and a substrate, thereby providing an improved higher capacity memory module as replacement for a DIMM.

This invention further provides improved ECs and methods of fabricating the ECs. In a first embodiment, an EC that is at least partly recessed (embedded) into the sidewall of a chip is provided, such that a plurality of embedded ECs along the edge of a chip can have uniform pad pitch but different cross-sectional areas according to the depth of embedding, thereby providing economy through tailoring of the ECs according to current carrying requirements. In a second embodiment, an EC having a gull lead that protrudes outside the chip perimeter and below the rear surface of the chip is provided, thereby providing improved inspection and access to contacts.

### BRIEF DESCRIPTION OF THE FIGURES

In the accompanying drawings:

FIG. 1 (PRIOR ART) is a symbolic view of a conventional DIMM memory module;

FIG. 2A depicts a perspective view of a stack of chips incorporating embedded ECs and TSV connectors between chips according to an embodiment of the invention, with interior portions depicted in phantom;

FIG. 2B is a cross-sectional view of the stack of FIG. 2A, showing the connectors in greater detail;

FIG. 2C is an expanded view of the embedded EC of FIGS. 2A, 2B;

FIG. 2D depicts a perspective view of a chip with embedded ECs that have alternate cross-sectional shapes that may be used in conjunction with the ECs depicted in FIGS. 2A-2C;

FIG. 3A depicts a perspective view of a stack of chips incorporating gull lead ECs and TSV connectors between chips, according to another embodiment of the invention;

FIG. 3B depicts a cross-sectional view of the stack of FIG. 3A, showing the connectors in greater detail;

FIGS. 4A, 4B are perspective views of alternate embodiments of ECs, including features of the embedded and the gull lead ECs of FIGS. 2A-3B;

FIG. 5 depicts a perspective view of a high capacity memory module including a plurality of stacked IC memory chips which incorporate features disclosed in conjunction with the embodiments described in FIGS. 2A-4B;

FIG. 6 depicts a perspective view of a compact memory module including stacked IC memory chips which incorporate features disclosed in conjunction with the embodiments described in FIGS. 2A-4B;

FIG. 7 depicts a perspective view of an assembly including IC memory chips and a memory controller interconnected in a single stack which incorporates features disclosed in conjunction with the embodiments described in FIGS. 2A-4B;

FIG. 8 depicts a perspective view of an alternate embodiment of an assembly including IC memory chips and a memory controller interconnected in a single stack according to features described in conjunction with FIGS. 2A-4B and 7;

FIG. 9 is a flow diagram describing a process for fabricating a stack of IC chips that incorporates features described in conjunction with FIGS. 2A-8;

FIG. 10 depicts a cross-sectional view of one chip incorporating gull lead ECs and TSVs for connection to a substrate, according to yet another embodiment of the invention;

FIG. 11 is a flow diagram describing a process for wafer level packaging used in fabricating a stack of IC chips designed according to the process of FIG. 9, which incorporates features described in conjunction with FIGS. 2A-4B;

FIG. 12 is a flow diagram describing a process for forming an embedded edge connector depicted in FIGS. 2A-2C;

FIG. 13 depicts a fragmentary top plan view of a wafer showing embedded ECs and saw streets from which individual IC chips of FIGS. 2A, 2B can be singulated;

FIG. 14 is a flow diagram describing an alternative method for forming an embedded EC and/or gull lead EC depicted in FIGS. 2D-4B;

FIG. 15A depicts a fragmentary top plan view of a wafer showing a trench with recesses, and saw streets, from which individual chips of FIGS. 2D-4B can be fabricated;

FIG. 15B depicts a cross-sectional edge view of the wafer of FIG. 15A, showing a trench and a saw street, in profile;

FIG. 16 is a flow diagram describing an alternative method for forming an embedded EC depicted in FIG. 2D.

### DETAILED DESCRIPTION

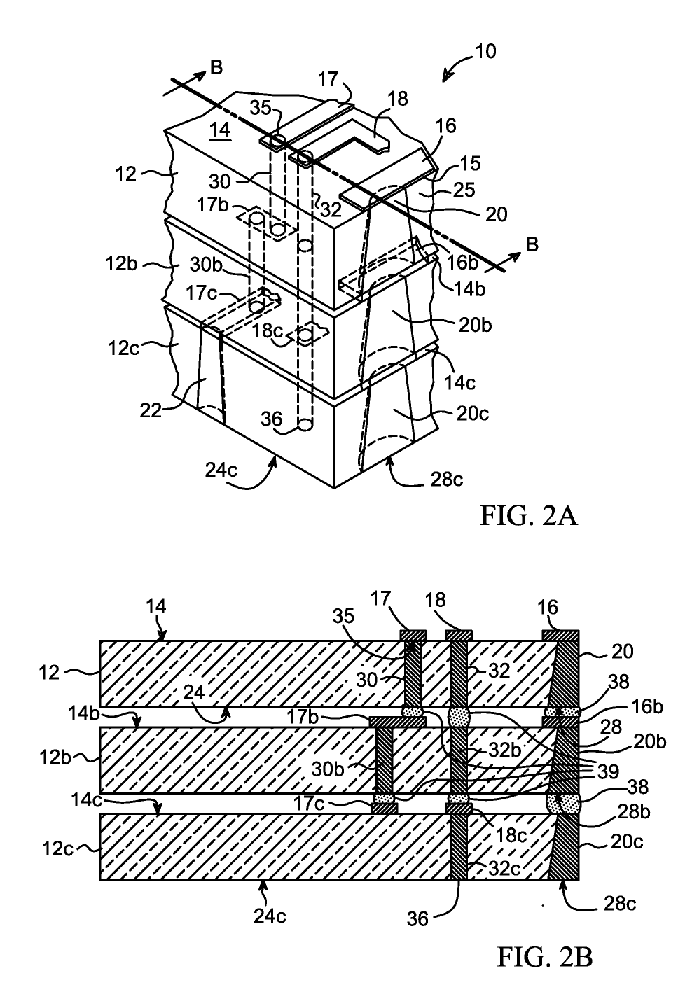

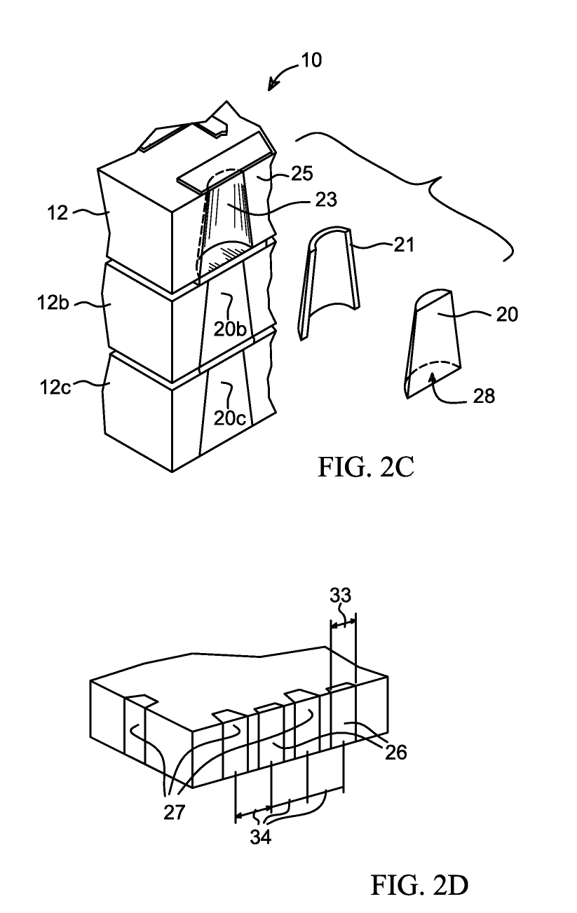

A stack of semiconductor chips are electrically interconnected to each other, and to another electrical component through a combination of edge connectors (hereinafter referred to as ECs) and through-silicon vias (hereinafter referred to as TSVs). FIG. 2A depicts a perspective view of a stack 10 of IC chips 12-12c incorporating EC and TSV connectors within and between chips according to an embodiment of the invention. The interior portions of the IC chips are depicted in phantom in FIG. 2A. The individual chips 12, 12b, 12c, can be mechanically attached to each other using known techniques, including flip-chip interconnections between TSVs, and epoxy encasements around portions of the stack. Electrical connections between circuits on the chips (and to a substrate, not shown), according to an embodiment of the invention, are illustrated in greater detail in FIG. 2B, in cross-sectional view taken along line B-B identified in FIG. 2A. It should be noted that specific dimensions and components of the figures presented herein may not be to scale. For example, in FIGS. 2A-4B, 10, the chips are depicted, for purposes of clarity, as being disproportionately thick when compared to the length and/or width of the active surface or rear surface of the IC chips. In a similar manner, the cross-sectional area of ECs and TSVs depicted within the figures may be disproportionate to the thickness of their respective IC chips. Throughout the disclosure, TSVs and EC may also be described according to a specific geometric shape. These details are offered for illustrative purposes only, and are not intended to limit the scope of the appended claims, which comprehend alternative shapes and dimensions for these structures. As noted above, the exterior surface of an IC chip extending between the upper and lower surfaces is referred to variously as the edge or sidewall of the IC chip. Because IC chips are typically polygonal, individual sides may be collectively referred to in the plural, “edges.”

Referring still to FIGS. 2A and 2B, the reader will understand that the IC chips include various circuit elements such as transistors, resistors, capacitors, and interconnecting wires, also called traces, lines, or leads, which are generally metal but sometimes can also be formed of other electrically conductive material, such as highly doped semiconductor. The circuit elements are typically formed within a region or layer near one surface on an IC wafer, conventionally referred to as the active or circuit surface or side, before the wafer is separated (singulated, diced) into IC chips. Because these structures may number in the millions, those skilled in the art readily appreciate that such structures, which are included in a typical IC chip, have been omitted from the figures for purposes of clarity. The portions of traces whereby an IC chip is electrically connected to an external system are conventionally referred to as input/output (I/O) terminals, pads, contacts or contact terminals, and are typically located at the surface of the active layer. Portions of traces 16, 16b, 17, 17b, 17c, 18, 18c on active surfaces 14, 14b, 14c are illustrated in the figures, and in the interest of clarity, other circuit elements are not shown.

According to an embodiment of the invention, ECs 20, 20b, 20c, 22 and TSVs 30, 30b, 32, 32b, 32c implement an electrically conductive path from the active surface of a first IC chip to the active surface of an adjacent IC chip in an IC stack 10, or to the bottom side 24c of the stack for connection to a board or substrate (not shown), as depicted in FIGS. 2A, 2B. The ECs and TSVs thus provide interconnections between chips, and from a chip to a circuit board or other external system element, according to circuit function, as will be further described hereinbelow, after first describing physical aspects of the interconnections in further detail.

The ECs depicted in FIGS. 2A, 2B are a first improved type of EC that is different in some structural aspects from conventional ChipScale™ EWCs (Chen, op. cit., Richards, op. cit.). While a conventional EWC is on the surface of the edge (sidewall) of the chip, the first improved EC is also partially or wholly embedded (recessed) in the edge of the chip, and is herein referred to as an embedded edge connector (EEC). It should be noted that the term EC will be used herein to refer inclusively to conventional EWCs, to EECs, and also to other improved ECs that will be described hereinbelow. With respect to ECs in a stack of chips, it should be further noted that a circuit trace with first and second terminals may be disposed on a surface of a first IC chip, wherein the first terminal of the circuit trace is electrically coupled to the EC, and the second terminal of the circuit trace terminates somewhere on the surface of the first IC chip. In one embodiment, the second terminal of the signal trace may be electrically coupled with a die terminal on the surface of the first IC chip. In another embodiment, the second terminal of the circuit trace may be aligned with a die terminal of an adjacent IC chip in an IC stack, facilitating a flip-chip type connection between stacked chips. These embodiments are not mutually exclusive, and may be used in conjunction with each other.

According to the embodiment of the invention, as shown in FIGS. 2A, 2B, an EEC 20 is a column of conductive material that is embedded in the edge of chip 12. The EEC 20 is separated and electrically insulated from the material of the chip by an intervening layer of electrically insulating material 21 such as silicon dioxide, another oxide, a nitride, or a polymer. An embodiment of insulating layer 21 is visible in the exploded view of FIG. 2C, which illustrates also a recess 23 (sometimes also termed “cove”) in the sidewall 25 of chip 12 wherein the insulating layer 21 and EEC 20 are disposed. It should be noted that the EECs 20-22 are shown to be slightly conical in shape; however the geometry of an EEC can be selected to have a different shape, which can be tailored individually, according to the invention, as will be described in detail hereinbelow, to achieve a desired electrical impedance and current-conducting capability according to the circuit application. In an alternate embodiment, the EEC can have another suitable shape, with equal effect, according to the application. For example, the EEC can be substantially cylindrical, or alternatively, it can be elliptical, or rectangular or trapezoidal as illustrated in FIG. 2D, wherein EECs 26 are wider along the edge of the chip than the distance they are recessed (embedded) into the chip, and EECs 27 have the shape of trapezoidal columns recessed farther into the chip, and have larger cross-sectional area than EECs 26, both having approximately the same width 33 and uniform spacing or pad pitch 34. Throughout this disclosure, therefore, specific examples depicting conical, cylindrical, or other geometric shapes or sections, are so limited for economy of expression, and should not be construed as limiting the appended claims, which fully envision TSVs and EECs exhibiting alternative geometric shapes and sections.

The EEC 20 on chip 12 is electrically (and mechanically) connected to a circuit trace 16 disposed on the active surface 14 of the chip, near the right hand edge 15 of the chip. EEC 20 extends the height of sidewall 25, from the top surface 14 to the bottom surface 24 of IC chip 12 (see FIGS. 2A, 2B). The reader will appreciate that geometric and directional references herein, such as “right,” “left,” “top,” or “bottom” are offered only for purposes of illustrative clarity, and are not intended to functionally limit the geometric orientations of the embodiments described herein, or otherwise limit the appended claims. A contact surface 28 formed on the bottom of EEC 20 can make electrical contact with an adjacent electrical contact, such as trace 16b on active surface 14b of adjacent chip 12b. In an alternative embodiment, the bottom contact surface 28b of EEC 20b can make electrical contact with the upper portion of an adjacent EEC 20c. The attachment and electrical contact to the adjacent chip can be made either through direct mechanical contact to an intermediate material or an extruded or plated up portion of the EEC material, or through various connective methods known in the art, such as conductive pastes, conductive bumps or solder balls 38 as shown, for example, electrically coupling EEC 20 and trace 16b, and EECs 20b and 20c, in FIG. 2B. The attachment and electrical contacting can employ heating, or cold (ultrasonic) welding, or other suitable technique and materials known in the art. As shown in FIG. 2B, the bottom contact surface 28 of EEC 20 rests on circuit trace 16b, which is disposed vertically above edge connector 20b, with circuit trace 16b disposed therebetween, and completing electrical contact between the two edge connectors. It will be readily appreciated, however, that a circuit trace such as 16b may be coupled to any conductive structure, including an edge connector not disposed vertically beneath edge connector 20, a TSV, or an I/O die terminal on the active surface of the adjacent IC chip. Alternatively, the contact surface of an EEC can be disposed directly on the contact surface of a TSV, or the contact surface of an I/O terminal on the adjacent IC chip.

Various alternative signal path embodiments are illustrated in conjunction with FIGS. 2A, 2B. Referring to FIG. 2B, the upper contact surface, sometimes also referred to as a bond pad, of TSV 30 is directly coupled with the lower surface 35 of circuit trace 17, which is disposed on the active surface 14 of a chip 12, whereas the lower contact surface of TSV 30 is coupled to circuit trace 17b through an intermediary conductive member, shown, by way of example, as a solder ball 39. The appended claims, however, fully envision alternative types of intermediary conductive members, such as conductive pastes, metallic bumps made from materials other than solder, an extruded portion of the TSV material, or other suitable means known in the art. Circuit trace 17b is disposed on the active surface 14b of chip 12b which is stacked directly beneath, and adjacent to, chip 12, in stack 10. By integrating TSVs and circuit traces in the same signal path, signal continuity can be established through TSVs which are not vertically aligned, but are in different IC chips of the same stack. The bottom contact surface of TSV 30b is coupled to circuit trace 17c, which can be seen in FIG. 2A as being coupled with EEC 22. By this arrangement, the reader will further appreciate that a circuit trace can be used to integrate a TSV and an EC in a common signal path.

A signal path consisting of multiple vertically aligned TSVs 32, 32b, 32c disposed within adjacent IC chips 12, 12b, 12c of a stack 10 can include embodiments wherein adjacent vertically aligned TSVs 32, 32b are directly coupled (not shown) through processes such as cold sonic welding, or electrically coupled (with optional mechanical coupling) through a single common intermediary connective member, shown, by way of example, as a solder ball 39 coupling TSVs 32 and 32b in FIG. 2B. Alternatively, vertically aligned TSVs 32b and 32c are electrically coupled by multiple intermediary members, shown, by way of example, as solder ball 39 and circuit trace 18c. When a circuit trace is used as an intermediary electrical coupling of vertically aligned TSVs, another point on the circuit trace will preferably be electrically coupled with a third terminal. However, the third terminal is not shown in FIG. 2A, as the illustration of circuit trace 18c is delimited just beyond its junction with TSVs 32b and 32c, in the figure. Contact surface 36 disposed at the bottom of TSV 32c is available for electrical and/or mechanical connection to a circuit board or substrate (not shown).

Referring to FIGS. 2A, 2B, those skilled in the art will readily appreciate that an electrically continuous signal path across an IC stack 10, from the upper surface of the uppermost IC chip 12 in the stack, to the bottom surface of the bottom most IC chip 12c in the stack, can be achieved entirely through a sequence of EECs 20, 20b, 20c, as well as through a sequence of TSVs 32, 32b, 32c and through a mixed sequence comprising TSVs 30, 30b and EEC 22, traversing the successive IC chips 12, 12b, 12c. By aligning the bottom contact surface 28c of EEC 20c, and likewise the bottom of EEC 22 and the bottom surface 36 of TSV 32, with respective one or more contact pads on an adjacent electrical structure such as a circuit board (not shown), the conductive path can be extended to an external device or system, the active surface of yet another chip, a power or ground source, or any other electrical structure.

### Alternative Dual Interconnection Embodiments

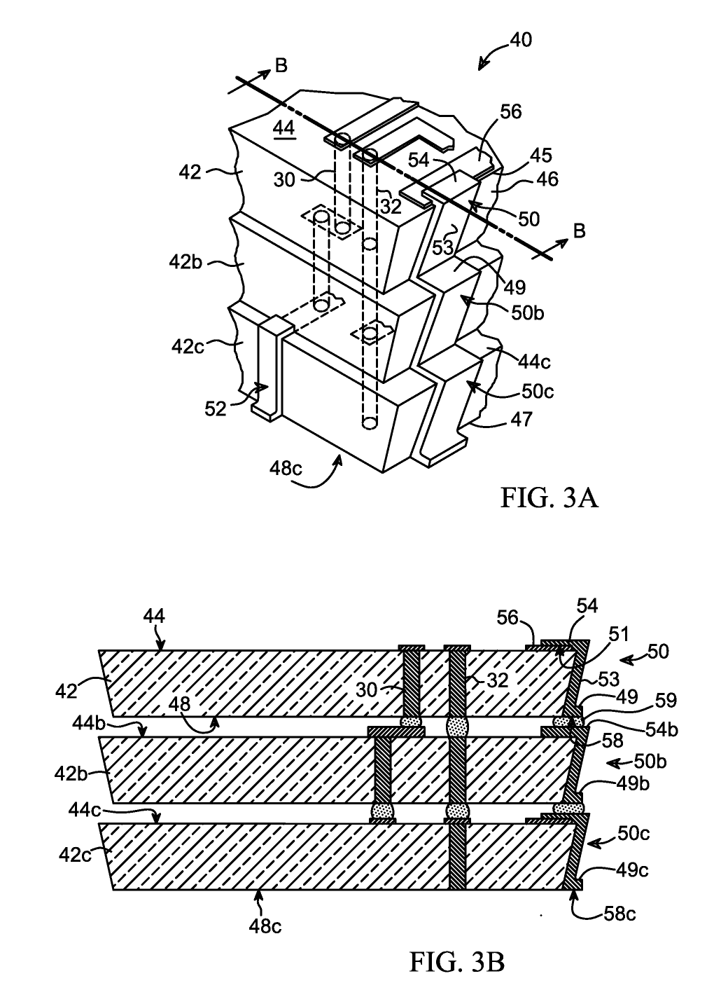

As used herein, “dual interconnection” refers to chip structures incorporating two interconnection technologies (connector types), TSVs and ECs, selected according to signal characteristics, according to the method of the invention. In the embodiment illustrated in FIGS. 3A and 3B, a stack of chips 40 are electrically interconnected to each other by a combination of TSVs and a second improved type of ECs, herein referred to as gull lead edge connectors (GECs). A GEC is similar to a ChipScale™ EWC, but instead of folding around the bottom edge of a chip and having the rear contact surface inside the chip perimeter as described in Chen (id.), Richards (id.), a GEC, for example, GEC 50 in FIGS. 3A, 3B, has a bottom contact surface 58 outside the chip perimeter, under a lower tab portion 49 extending distally from the edge of the chip. A GEC can also have an upper tab portion 54, as in the ChipScale™ EWC, for connection to a terminal on the upper (active) surface of the chip. FIG. 3A depicts a stack of chips 40 in fragmentary perspective view, and in cross-sectional view in FIG. 3B (taken along a line B-B identified in FIG. 3A). The stack 40 includes a plurality of IC chips, identified in this example as IC chips 42, 42b, 42c, each chip comprising GECs and TSVs, such as TSVs 30 and 32 and GEC 50 identified in IC chip 42; GEC 50b identified in chip 42b; and GECs 50c and 52 identified in chip 42c. Each of the IC chips of FIGS. 3A and 3B depicts an inverted pyramidal shape, such that the active surface of the middle chip is not completely obscured by the lower surface of the upper chip, and the active surface of the lower chip is not completely obscured by the bottom surface of the middle chip. This inverted pyramid design facilitates interconnection between upper 54 and lower 49 tab portions of GECs on adjacent chips, as discussed in greater detail below. Alternatively, the interconnection of GEC tabs as depicted in FIGS. 3A and 3B can be achieved by stacked IC chips depicting progressively greater surface area of their active surface, moving downward in the stack.

However, vertical stacking of un-tabbed EWCs with contact surfaces on the bottom side of the chip according to the ChipScale™ process (Chen (id.), Richards (id.)), or alternatively, as illustrated in the EEC embodiments of FIGS. 2A-2D, can be achieved on rectangular IC chips having a uniform area on their respective active surfaces.

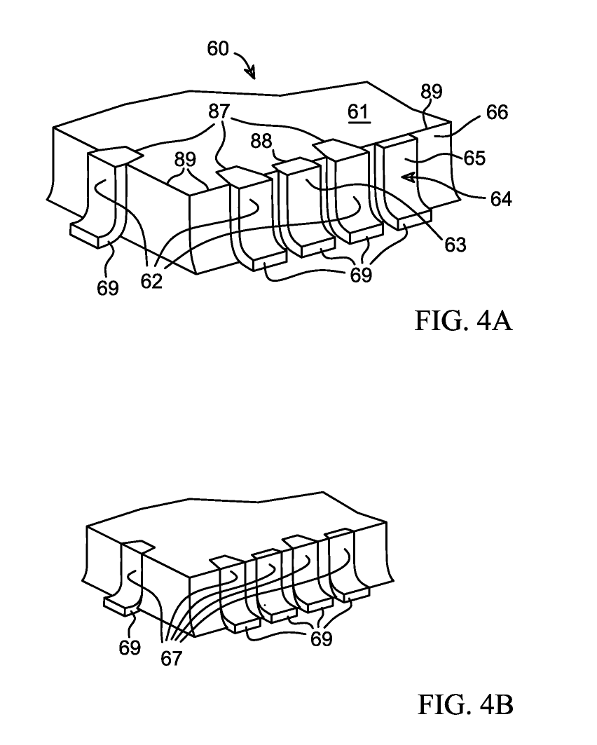

The GECs 50, 50a, 50c, and 52 depicted in FIGS. 3A, 3B, each include an upper tab portion such as 54, a lower tab such as 49, and a strip of conductive material, such as strip 53 of GEC 50, disposed on, and conforming to the surface of sidewall 46, and extending between the upper and lower tabs. (As shown in FIGS. 4A-4B, GECs variously may be disposed on the surface of a sidewall, or embedded therein.) GEC 50 bends downward from its upper tab 54 to form strip 53 proximate to the edge 45 of the IC chip 42 where the active surface 44 intersects the sidewall 46. (As used herein, the term “bend” is not intended to describe a manufacturing process of stressing and deforming a rigid conductive member, nor a geometric structure resulting from such deformation. Rather, the term “bend” is simply used to describe a geometric change of direction of the conductive path of an EC, and/or the angled corner defined by the intersection of these segments.) The lower surface 51 of the upper tab portion 54 of the upper GEC 50 rests against a conductive circuit trace 56 disposed near the edge 45 of chip 42 on its active surface 44. The strip 53 extends downward along the sidewall 46 of IC chip 42. Within the embodiment depicted in FIGS. 3A and 3B, the middle and bottom GECs 50b and 50c are configured with the same geometric features of the upper GEC 50. This uniformity, however, is offered only by way of example. The GEC embodiments of FIGS. 3A and 3B may interspersed between other EC embodiments on the same IC chip, or conductively stacked above or below other EC embodiments, including but not limited to the EEC embodiments depicted in FIGS. 2A-2D.

For example, an EC embodiment can include features of the EEC and GEC embodiments. FIGS. 4A, 4B, 2D depict multiple alternative embodiments of ECs. In FIG. 4A, EECs 62 and 63 are partially embedded (recessed) into sidewall 66 of IC chip 60 and partially protruding from the sidewall, and EC 64 is wholly protruding, with strip portion 65 on the surface of sidewall 66, all having distally extending (gull lead) lower tab portions 69. For purposes of clarity, upper tab portions of ECs on the active surface 61 of chip 60 are not shown in the figure. FIG. 4B illustrates an alternate EC embodiment wherein EECs 67 are fully embedded in the sidewall of the chip, i.e., do not protrude beyond the outer surface of the sidewall, and have distally extending (gull lead) lower tab portions. In FIG. 2D, EECs 26, 27 are fully embedded in the sidewall, without distally extending lower tabs, and thus have lower contact surfaces within the chip perimeter. The sidewalls (e.g., sidewall 66 of chip 60 of FIG. 4 and sidewall 46 of the upper IC chip 42 of FIGS. 3A, 3B) are depicted as planar surfaces for exemplary purposes. This depiction is not intended to limit the appended claims, which envision alternative shapes for the sidewalls of IC chips used in conjunction with the EC embodiments described within this disclosure.

With reference again to FIGS. 3A, 3B, the bottom of each of the GECs 50, 50b, 50c bends outward to form a lower tab portion, identified as element 49 on the upper gull lead edge connector (GEC) 50. The lower tab portion 49 of GEC 50 has a bottom contact surface 58 conductively coupled with the upper tab portion of the adjacent EC 50b. Although the bottom contact surface 58 is depicted within FIG. 3B as being flush with the bottom surface 48 of IC chip 42, alternative embodiments are envisioned wherein the bottom contact surface 58 is recessed slightly above the bottom surface 48 of its respective IC chip 42, or extending slightly beyond the bottom surface (the back side) 48 of the chip. As depicted in FIG. 3B, the bottom contact surface 58 can be mechanically and/or electrically coupled to the upper surface of the upper tab portion 54b of an adjacent GEC 50b by a conductive bump or solder ball 59. The mechanical attachment and/or electrical contact of the bottom surface 58 of the lower tab 49 to the adjacent GEC 50b can alternatively be achieved by some other intermediate layer, or through direct connection which may be electrical only, or may include direct mechanical connection by a cold (ultrasonic) weld, or other suitable technique known in the art.

Within FIG. 3B, distinct embodiments are disclosed. GEC 50 depicts an upper tab 54 resting on a conductive circuit trace 56 disposed on the active surface 44. The bottom GEC 50c depicts a similar embodiment. In contrast, the center GEC 50b depicts an upper tab 54b resting on a non-conductive section of the active surface 44b of its respective IC chip 42b. The center embodiment 50b illustrates a GEC that transmits a signal between the chip 42b and chips 42, 42c, which are not adjacent to each other, but are adjacent to chip 42b, without transmitting the signal to any circuit within chip 42b.

Although FIG. 3B only discloses embodiments in which the bottom contact surface of a lower tab 49, 49b, of a GEC is electrically connected (through solder) to the upper tab of a GEC disposed on an adjacent chip, embodiments are also envisioned wherein the bottom surface 58 of the lower tab 49 is electrically coupled to a trace disposed on the active surface of an adjacent chip, either through direct contact or through an intermediary connecting member such as a solder ball. Alternatively, the lower tab 49 may be mechanically and/or electrically coupled with the top of a TSV on the adjacent chip. In still another embodiment, the strip portion 53 of an EC can extend around the bottom edge of chip 42 to its back side 48, providing a bottom contact surface, for example, on a standoff, which could be used, for example, in a ChipScale™ EWC embodiment.

In the embodiments described throughout this disclosure, the reader will appreciate that a circuit trace may be electrically coupled with any known circuit element, including but not limited to, ECs, TSVs, I/O terminals, die bond pads, wire bonds, and flexible circuits coupling a circuit trace to another electronic device. Moreover, a circuit trace may electrically interconnect any combination of these circuit elements.

Although the IC chips of FIGS. 3A and 3B depict an inverted pyramidal shape, applications are envisioned wherein the GEC embodiments of FIGS. 3A and 3B, or some features or elements of those embodiments, are used in conjunction with IC chips depicting alternative profiles, such as a rectangular profile. This embodiment does not require inverted pyramidal shaped chips, or progressively greater surface area on adjacent chip, as described above. It can be seen with reference to FIGS. 3A and 3B, that an electrical connection from the active layer 44 of chip 42 can be transmitted through vertically stacked GECs 50b and 50c, and wherein the bottom portion of the GEWCs extends outward from the edge of the chips, as lower tabs 49b and 49c, the latter tab 49c having a bottom contact surface 58c near edge 47 and bottom 48c of the stack, for connection to pads on an adjacent substrate or other chip.

### Method of Partitioning Signals for Connection by TSVs and ECs:

According to an embodiment of the invention, interconnections for signal paths transmitting high-speed I/O signals from the circuit side of a chip to the rear of the chip are preferably implemented in form of TSVs in order to minimize circuit length in the critical signal paths, and if necessary, to isolate them from the fields generated by higher current signal paths. High-speed signals, sometimes also referred to as critical or integrity-sensitive signals, are herein understood to include signals for which low signal transmission latency is desirable and which are sensitive to distortion, noise and electromagnetic interference. In a memory chip, for example, the signals on a data bus can be considered high-speed signals. It will be recognized by those skilled in the art that the layout of circuits on adjacent chips in the stack, and on a substrate, can be suitably adapted for such interconnection. In an embodiment, the cross-section of TSVs will be advantageously limited in size to a predetermined diameter. According to this embodiment, slow-speed signals, which typically have high peak current requiring connectors of a greater cross-sectional area, are preferably implemented in form of ECs, thereby limiting the number of TSVs and thus providing a more compact and lower-latency IC layout on the chip, and also segregating the TSVs from the field effects of high current signals. Embodiments are envisioned wherein the predetermined limit for the diameter of a TSV is approximately 20 microns. Alternative embodiments are envisioned in which the predetermined limit of TSV diameters within an IC chip is 15 microns, 12 microns, 10 microns, 9 microns, 8 microns, 7 microns, 6 microns, 5 microns, 4 microns, 3 microns, 2 microns, and 1 micron.

In contrast to the routing of high-speed I/O signals through TSVs, interconnections for slow-speed signals, including power and ground, are preferably implemented ECs. Power and ground signals are usually slow-speed, non-critical signals, reasonably impervious to noise, parasitic capacitance, etc. Power and ground signals typically exhibit high peak current, and therefore require connectors having large cross-sectional area to reduce signal path impedance. If power and ground were routed through TSVs, therefore, two distinct disadvantages would inure. First, the large cross-sectional area of a power or ground TSV consumes valuable circuit area. Moreover, since a TSV is surrounded on all sides by transistors or other micro-circuit structures, routing power or ground current through a TSV can produce field effects that have a deleterious impact on the integrity of transistor states. By utilizing ECs for high-current connections, such as power and ground signals, the deleterious effect of high current signals on other signals connected through TSVs located away from the chip edge, is reduced, and more easily segregated. Moreover, by transmitting high current signals such as power and ground through ECs, less circuit area is consumed within the chip, thereby enabling a more compact and lower-latency circuit layout and/or a greater number of TSVs to be formed within each chip. Conversely, by connecting most high-speed signals through TSVs rather than through ECs, more space is available for ECs, which can thereby be fabricated at greater widths, thereby exhibiting lower impedance in signal paths appropriate for power connections and high current switching, without appreciable voltage drop or voltage spikes, or alternatively, ECs can be fabricated at greater spacing (pad pitch) between connectors, which can reduce packaging cost. ECs in form of EECs can be recessed to different depths in the sidewall of a chip (while maintaining a uniform pad pitch), according to the peak current of the signal connected through the EEC, which can save conductive material, in comparison to an embodiment wherein all ECs have the same cross-section. These benefits would not be available if only one type of connector, either TSVs or ECs alone, were used in the chip.

Thus, according to an embodiment of the invention, the I/O signals of an IC chip, which are connected to respective I/O terminals on the circuit side, also referred to as the top side or active side of the chip, are partitioned into two groups, for connection to contact surfaces at the rear of the chip. The first group are connected by ECs which can be EECs (and also GECs, according to the application), and the second group are connected by TSVs. According to the embodiment described hereinabove, the first group includes low-speed signals, including power and ground, and the second group includes high-speed signals.

In alternate embodiments, it can be desirable to include other signals, such as chip select signals, in the first group, and low current signals, in the second group. Within IC stacks comprising multiple IC chips connected to the same data bus, it is common to have a separate control line for each chip, termed chip select (CS), by means of which an individual chip can be selected to be connected, or not connected, to the data bus during a sequence of processing operations. For example, in a multichip memory module, a high CS signal value to one memory chip and a low CS signal value to the others, can be employed by the memory controller to connect a particular memory chip to the processor, as current memory. CS signals typically exhibit low current levels, and. according to one embodiment, CS signals can be transmitted through TSVs. There are architectural reasons, however, for connecting some or all CS signals through ECs. One reason is that if TSVs were used for CS signals in embodiments wherein at least a subset of chips of the stack have the same circuit layout, the greater the number of IC chips in the subset (which can comprise the entire stack, as in a memory stack), the greater the percent of valuable chip space is wasted.

The disadvantage of utilizing TSVs for CS connections in this case can be illustrated by imagining an IC stack with fifteen chips, and wherein all CS signals are routed through TSVs. Large memory modules often comprise a plurality of similar chips, and the memory circuit terminal for the CS signal is typically disposed in the same location on each chip of the plurality. Therefore, in a stack of fifteen chips, all fifteen chip selection terminals would be vertically aligned. However, CS signals passing through a stack require individual circuit paths and thus cannot share vertically aligned connectors, but need to be offset from each other within the circuit plane. The bottom chip of our imaginary stack would therefore require fifteen TSVs, one for each CS signal. The first TSV would provide the CS signal controlling the bottom chip, and fourteen additional TSVs would transmit pass-through signals for the other fourteen CS signals controlling the other fourteen chips in the stack. The second chip requires fourteen TSVs, one for its own CS signal, and thirteen more for CS signals passing through. The third chip requires thirteen TSVs, and so on, and the top chip of the stack requires one TSV. Although the uppermost chip would require only one TSV (for its own CS signal), because the circuit layout of all the chips in the stack remains constant, they would all have fifteen TSVs, or at least the area reserved for fifteen TSVs. For the bottom chip, all would be utilized; and for the uppermost chip, only one would be utilized and the other fourteen would serve no purpose whatsoever. The higher one goes in the stack, the more non-functional TSVs there are in each chip, wasting valuable circuit area. The utilization of the TSVs would be just over 50%. Moreover, recent research suggests an increased risk that crystal structure defects will develop within a chip in the circuit area near closely spaced TSVs.

Alternatively, embodiments wherein each chip of a stack has a different circuit layout, tailored to accommodate a different TSV location, would save functional chip area but would have the disadvantage of requiring a plurality of layout versions of a stackable chip (adapted to be attached and interconnected to other chips in a stack and further to a circuit board or substrate). Using the above example of a stack of fifteen chips, the bottom chip would have fifteen TSVs, and the top chip only one TSV. This embodiment, while reducing the cost by having a smaller average chip size and thus more chips per wafer, however, increases the cost, owing to the complexity of manufacturing and handling a greater number of distinct chips and wafers (or portions of wafers), one for each stack level or position.

The disadvantages of routing CS signals through TSVs can be avoided by connecting CS signals (and similar pass-through signals) through ECs. Pass-through signals are herein defined as those signals between a chip of the stack and the external system that pass through other chips without connecting to circuits thereon. By reducing the use of TSVs within the functional circuit area, circuit elements may be packed closer together, thereby reducing signal transmission latency within the circuits on a chip and increasing the capacity of a chip. Accordingly, it is advantageous to connect CS signals and other non-critical pass-through signals through ECs (and include these signals in the first group), according to the invention.

Contrariwise, TSVs are reserved for high-speed signals. High-speed signals may include, but are not limited to, critical signals, noise sensitive signals, skew sensitive signals, high frequency signals.

It should be understood that in yet alternate embodiments it may be advantageous to constitute the first and second groups of signals and top side terminals, which are connected by ECs and TSVs, respectively, in a manner different from the embodiments described hereinabove, while still retaining some of the advantages described.

The architectural flexibility afforded by the embodiments described above can be further appreciated by briefly looking again at FIGS. 2A and 2B. A continuous electrically conductive path extends from circuit trace 17 disposed on the upper surface of chip 12, to EEC 22 disposed along the left forward sidewall of the bottom-most chip 12c. The EEC 22 terminates at the lower surface 24c of IC chip 12c, forming a contact surface that can electrically couple with electrical contacts of another electrical structure such as a substrate, a memory controller, etc. From this illustration, it can readily be appreciated that any combination of TSVs, ECs (including EECs) and circuit traces can be used in conjunction to provide a conductive path from the memory controller (or substrate or other electrical device) on which a stack rests, to any die terminal or contact area on the active surface of any IC chip of the stack.

It can further be appreciated that an EC can distribute power, ground, or other high current signals to a plurality of TSVs. These TSVs may be disposed in different IC chips, the same IC chip, or combinations thereof. The EC may be coupled to these various TSVs through a single circuit trace extending across multiple TSVs, or through multiple circuit traces disposed within a stack. Thus, the EEC 22, which can have a large cross-section, can serve to aggregate current from a plurality of TSVs with small cross-section, thereby avoiding the need for a TSV with large cross-section within the active circuit area of chip 12c.

Increasing Memory Capacity Through Stacking with Dual Interconnection:

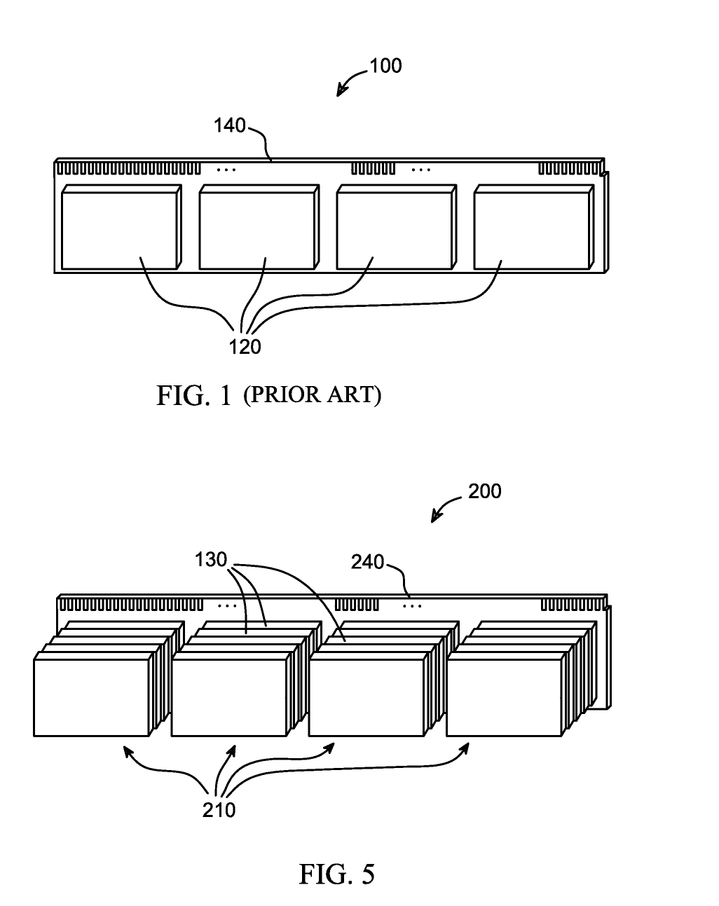

As noted above, memory modules often comprise a plurality of memory ICs. An example of a prior-art four chip DIMM is illustrated in FIG. 1. A more compact and higher memory-capacity replacement device can be achieved by stacking a greater number of interconnected memory ICs on top of each other. Stack height (i.e., the number of chips in a stack) is limited, inter alia, by signal routing capacity. By transmitting integrity-sensitive signals through TSVs, and using edge connectors for power, ground, and CS electrical paths, as described hereinabove, signal routing capacity can be appreciably increased beyond present levels, thereby allowing fabrication of memory modules that comprise more memory capacity per stack.

In contrast to the prior art module of FIG. 1, FIG. 5 depicts an embodiment of a memory module 200 incorporating the design features described herein. According to the example depicted in FIG. 5, memory module 200 comprises four chip stacks 210 mounted on a circuit board 240. Each stack comprises five memory chips, 130 which are equivalent in memory capacity to the chips 120 in FIG. 1, but designed according to the partitioning of signals for connection through TSVs and ECs as described herein, and interconnected with features taught in conjunction with FIGS. 2A, 2B, 2C, 2D, 3A, 3B, 4A, and 4B. In this embodiment, the electrical contact configuration on the edge of board 240 can include substantially the same conventional contact configuration as on the edge of board 140 of the module 100 of FIG. 1. However, because it has five times the memory capacity as the prior art memory module depicted in FIG. 1, a single memory module 200 as depicted in FIG. 5 can replace five DIMMs 100 depicted in FIG. 1.

A More Compact Memory Through Stacking with Dual Interconnection:

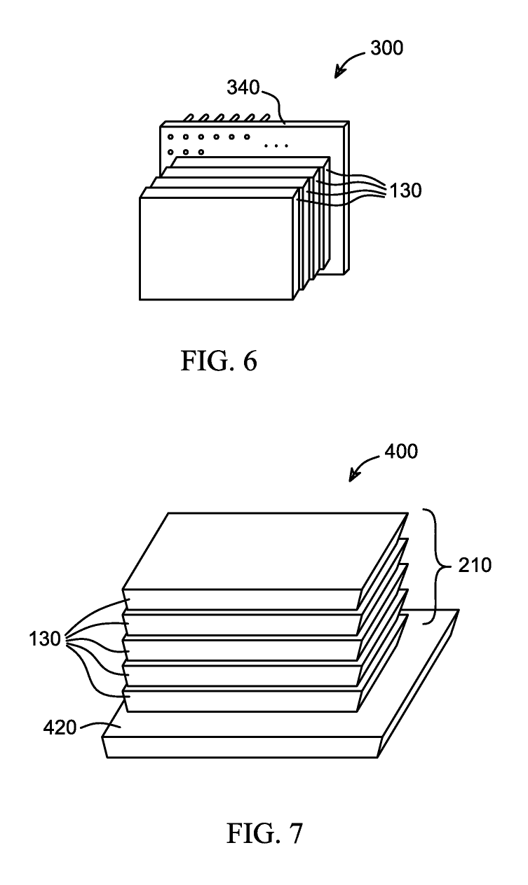

FIG. 6 depicts an embodiment 300 having four chips 130 stacked on a pin-grid type circuit board 340. The memory of each chip 130 is equivalent to the memory of the respective chips 120 of FIG. 1. However, through incorporating the design embodiments and features described herein, the chips 130 can be stacked, thereby achieving a more compact connection configuration that can have substantially the same capacity as the prior art memory module of FIG. 1. The pin grid configuration 300 of FIG. 6 is presented only as one alternate embodiment by which a more compact chip stack can be coupled to a motherboard or other electronic assembly component.

Compact Memory and Controller Modules Through Stacking with Dual Interconnection:

Another application can be appreciated by the embodiment 400 depicted in FIG. 7. The memory chips 130 of FIG. 7 are fabricated with both ECs and TSVs, as described herein, and configured to segregate signals through these respective transmission paths, as further described herein. The chips 130 are electrically interconnected in a stack configuration 210 utilizing interconnection features taught in conjunction with FIGS. 2A-4B. The stacked memory chips 130 are mounted on top of a memory controller chip 420.

Significant advantages ensue from the design of the memory module 400 in FIG. 7, in comparison to the prior art designs. Electrical transmission of a digital signal may require the charging or discharging of a conductive path to certain requisite voltage levels. As a consequence, the clock speed of a memory controller is limited, at least in part, by the time it takes to charge or discharge a conductive path between the controller and a memory chip controlled by the memory controller. The capacitive load of a signal path, however, is proportional to the length of the signal path. As a consequence, a reduction in length of the longest conductive path between a memory controller and a memory chip conductively coupled thereto may facilitate higher clock speeds of the memory controller. FIG. 1 depicts a prior art memory module 100 in which a succession of memory chips 120 are distributed lengthwise along the surface of a memory card 140, a geometric configuration requiring the greatest length between memory chips and, therefore, compounding the distance from the first memory chip to the last memory chip. In contrast, the stacking of memory chips 130 in FIG. 7 can significantly reduce the distance between the memory controller and the memory chip most distal from the controller, with the potential of facilitating faster clock speeds and more rapid digital storage.

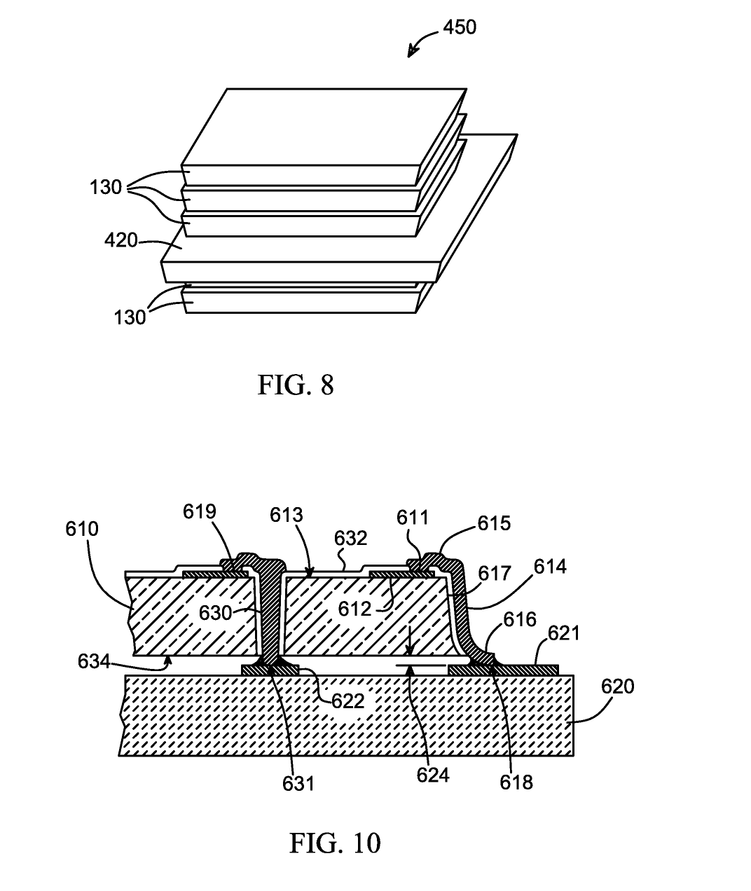

FIG. 8 depicts an embodiment 450 similar to FIG. 7, but wherein stacked memory chips 130 are disposed on opposite sides of the memory controller 420, further reducing the maximum transmission distance between the controller and the most distal memory chips coupled to the memory module.

### Method of Fabricating a Stacked Chip Module Incorporating Dual Interconnection:

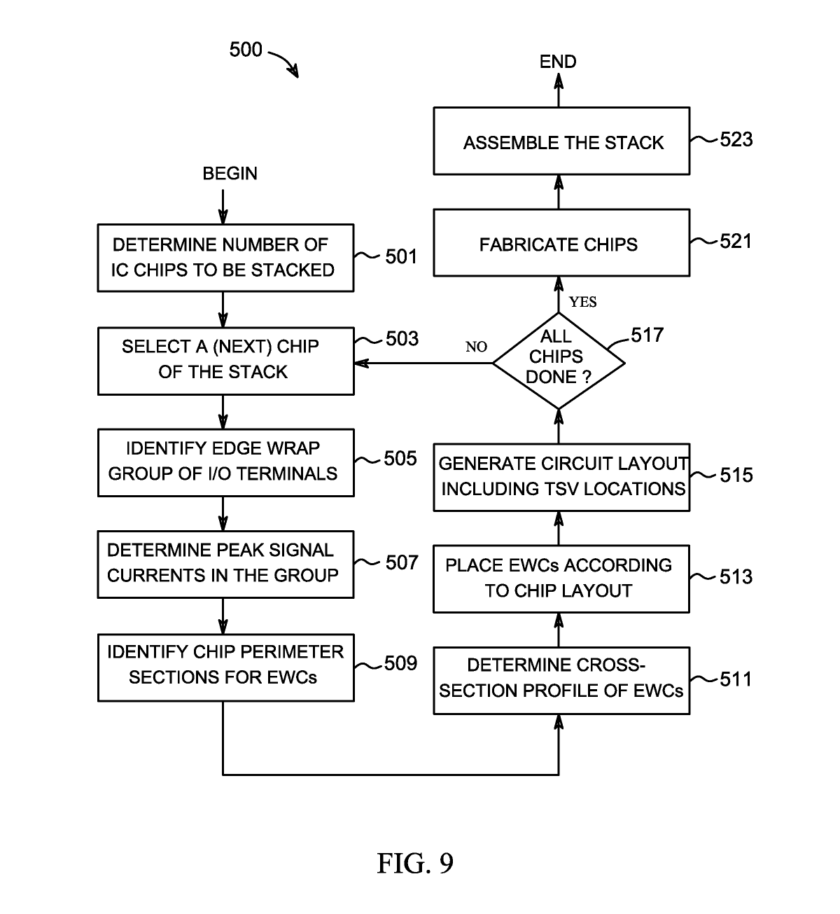

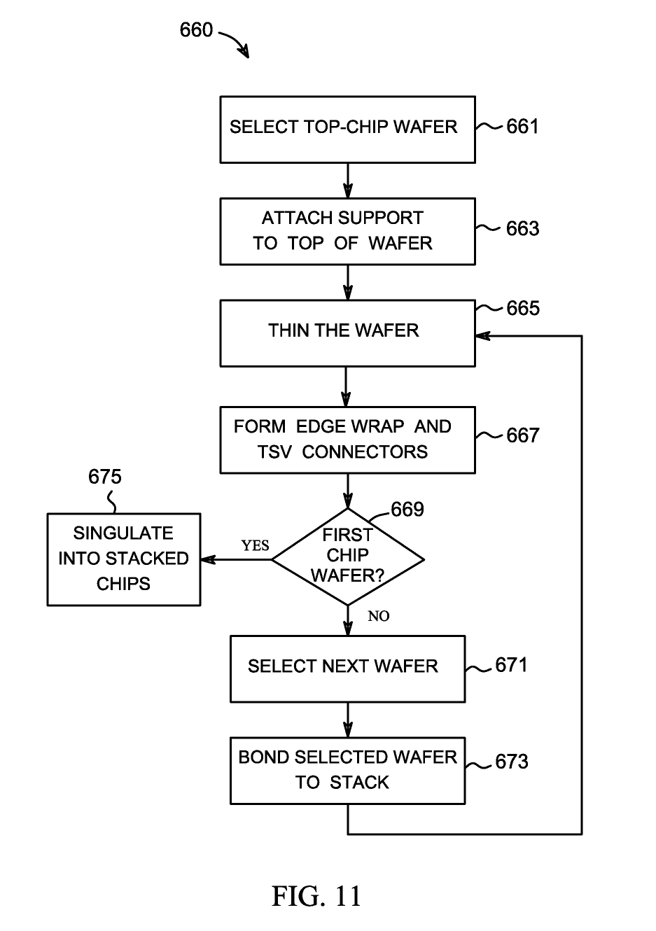

FIG. 9 depicts a sequence of steps 500 that illustrate, by way of example, a design and fabrication process for manufacturing a semiconductor module comprising a stack of IC chips interconnected by ECs and TSVs, according to features described above. Throughout FIGS. 5-10, the terms “semiconductor module” and “IC stack” are used somewhat interchangeably, with specific application toward semiconductor modules such as FIGS. 6 and 7, in which a single stack of IC chips is coupled with a substrate, memory controller, or other electronic structure (e.g., elements 340, 420 in FIGS. 6, 7, 8). This specific scope of the term “semiconductor module” in the processes described in FIGS. 9 and 11 is used only to simplify the description of these processes, and to avoid unnecessary redundancy or complexity of description. The appended claims fully comprehend the application of the design processes described in FIGS. 9 and 11 for the design and fabrication of semiconductor modules comprising multiple IC stacks, such as depicted in FIGS. 5 and 8.

The process 500 is configured to allow all of the IC chips (dice) within the module to use an identical wafer fab process, thereby reducing the costs of design and fabrication. However, the process 500 is not limited to such embodiments. At the same time, the process is configured to maximize the efficient utilization of circuit area within an IC chip. In broad terms, the process 500 begins at the circuit design stage of the IC chips that will be assembled within a semiconductor module, and/or the design of the wafer(s) from which the chips will be singulated. An identical wafer fab process for chips at all levels of a stack, and smallest circuit area for each chip, can be achieved by designing a semiconductor die such that power, ground, and at least some of the pass-through signals are connected, at least in part, through ECs (including EECs and GECs) formed on the sidewalls of the respective chips of the module, as described in conjunction with FIGS. 2A, 2B, 2C, 2D, 3A, 3B, 4A and 4B. The process 500 is an iterative process sequentially designing the IC chips designated for assembly in a common semiconductor module, one IC chip at a time. The iterative process begins with the “first” IC chip within the stack adjacent the substrate, memory controller, or other electrical structure forming part of the semiconductor module. The design process proceeds sequentially through adjacent chips of the stack until the “last” or “top” IC chip in the stack has been designed (i.e., the IC chip farthest from the substrate or external connection and mechanical support structure of the module). Within these processes, the “thickness” of an IC chip is understood as being approximately equal to the distance between the active surface and the rear surface of the chip, and the length of the periphery or perimeter is used to describe the peripheral distance (the perimeter) around the chip, in the surface plane, when measured along the sidewalls. In applications comprising square or rectangular IC chips, this will be equivalent to the combined length of all four sidewalls.

In step 501, the number of IC chips to be assembled in the stack is determined. The significance of this step will be readily appreciated in view of the design goals described in the embodiments described in conjunction with FIGS. 2A, 2B, 2C, 2D, 3A, 3B, 4A and 4B. If power and ground signals are to be connected through ECs, the peak current demand anticipated for transmission across a particular chip must be known to design an EC of adequate cross-sectional area. Some commands, such as “erase” or “reset” can be directed simultaneously to multiple IC chips within a stack, resulting in simultaneous power draw by multiple IC chips. Accordingly, embodiments are envisioned wherein the peak current demands of power and ground across a chip are related to the total number of chips in a stack. Additionally, if some, and preferably all, of the CS signals are to be transmitted through separate ECs, the design process requires that the designer first determine the number of IC chips that will be assembled in a common stack. As discussed above, many signals other than power and ground may have certain properties in common with CS signals, offering design incentives for the transmission of those signals through ECs as well. Again, the exclusive reference to CS signals and connection paths throughout the processes of FIGS. 9 and 11 is principally for the purpose of clarity and verbal economy. The appended claims fully envision the processes described herein to be used in conjunction with the transmission of signals other than CS signals, but wherein the advantages described in conjunction with CS signals would be similarly realized.

In step 503, the “next” chip of the stack is selected, according to stack level. In the first iteration through the process 500, step 503 starts with selecting the “first” chip of the stack, and the process advances to step 505. In subsequent iterations, the next chip in increasing order of stack level is selected, from the first to the last or “top” level in the stack. In further steps of the process, the currently selected chip may also be referred to as the “instant” chip.

In step 505, a “first group” of I/O signals are identified for connection across the thickness of the selected chip by ECs. The signals in the “first group” are chosen in view of signal characteristics suitable for transmission through ECs. According to a preferred embodiment, the first group of signals includes power, ground, and CS signals. As discussed earlier, other suitable signals can include other high current signals and non-critical pass-through signals. Power, ground, and chip select signals for the remaining chips in the stack (i.e., the chips at higher level above the instant chip and awaiting design according to the iterative process 500) will necessarily traverse the selected chip. Power for all of the IC chips in the stack is preferably distributed through a shared signal path using one connector (for each type of power signal, in case multiple voltages are supplied) in each of the chips at lower level in the stack, and ground is preferably routed in the same manner. However, embodiments are envisioned for connecting power and/or ground signals through multiple signal paths, including embodiments wherein power and/or ground signals to each IC chip have separate connectors. Appropriate widths, depths, position, and arrangement of the respective ECs are determined in subsequent steps. If the perimeter of a chip is not large enough to accommodate ECs for all of the signals in the first group, the signals are prioritized, for example, according to highest current draw, and the first group is redefined. I/O signals not identified for connection by ECs in this step are herein referred to as the “second group” of signals, and are identified for connection by TSVs, across the thickness of the instant chip.

In step 507, circuit simulation, using one of the computer based methods well known in the art, is performed on the circuit, which can include a plurality of chips, and a peak anticipated operational current level is determined for respective signal paths among the first group of signals. Alternatively, the current level may be estimated from calculations, specification tables for current draw through a particular circuit element, or simply based on the experience of the engineer or chip designer. Accordingly, the current level may be very exact and accurate, or may be a very rough approximation, according to the judgment of the designer and the method used to determine current draw.

In step 509, one or more sections of the periphery of the selected chip are identified as being available for fabrication of ECs. The one or more sections of the periphery may include the entire peripheral sidewall of the chip, or only a portion thereof. For purposes of this example, it is assumed that the entire perimeter is available for ECs. However, it can be readily appreciated that in some embodiments, it may be optimal to position some path length-sensitive I/O signals in the form of TSVs proximate an edge having no ECs, thus leaving only a portion of the periphery available for ECs.

In step 511, the cross-sectional profile of the ECs in the first group is determined. This may be based, at least in part, on the experience of the designer, and at least for the first chip of the stack, on industry standards for the application, such as the width and spacing (pad pitch) of external contacts of the chip. An engineer may use this, or any other number of design requirements, as a starting point for the design and location of ECs of the instant chip. Known methods of circuit simulation and circuit element modeling can be used to determine the cross-sectional area and shape of an EC according to the maximum current to be transmitted through the connector, and also according to dynamic aspects such as the effects of capacitive charging, coupling to nearby connectors, and series inductance, upon signal rise and fall times. Power and ground signals typically exhibit the highest current levels found in an IC chip, and are likely to require ECs with large cross-sectional area. The EEC and GEC embodiments of FIGS. 2D, 4A, 4B can be used to adapt the cross-sectional area of the connector to the maximum operating current for each signal among the first group, such that for the example of uniform width of the ECs (along the edge of the chip) a high current signal will use an EC having greater depth (thickness) and a lower current signal will use a thinner EC. Minimum EC size constraints imposed by manufacturing and packaging technology are incorporated into the EC profile determination in step 509. However, uniform depths, widths, or cross-sectional areas may be used among multiple ECs transmitting different current levels, provided that the cross-sectional area is adequate for the highest current among those multiple ECs. According to a preferred embodiment, the cross-sectional area of each EC is minimized to the smallest optimal cross-sectional area, to reduce the wafer area allocated to ECs and reduce the amount of conductive material used.

It will be appreciated that if more than enough space appears to be available on the periphery, a design engineer may identify additional signals to be included in the first group for connection by ECs. The above steps 505-511 can be repeated in view of the additional ECs. Conversely, some signals may be removed from the first group and re-designated for TSVs if the peripheral distance of the IC chip is not sufficient for the original partitioning. In an embodiment, signals re-designated for transmission through TSVs will start with the lowest peak current signals that were designated for ECs.

In step 513, specific locations around the chip periphery are designated for specific ECs corresponding to certain signals. In embodiments in which the entire perimeter is available for ECs, the location of an EC can be designated anywhere on the periphery.

In step 515, circuit layout of the selected IC chip is generated according to the locations of the ECs determined in the prior steps, for the first group of signals, and wherein the remaining I/O signals traversing the width of the chip, including high-speed signals, are identified for connection by TSVs, as described hereinabove.

In branch step 517, if the circuit layout is not yet completed for all chips of the stack, the process loops back to step 503, and the above design process, including steps 503-517, is repeated for the next IC chip adjacent the previous IC chip. It is understood that steps 503-515 have already predetermined the location of many of the TSVs and ECs of the next IC chip. It will be appreciated that at any point in the process described in steps 503-515, human intuition and other preferences of an engineer or designer can be incorporated and the steps modified accordingly. For example, in step 505 a designer could add additional factors to the partitioning process of I/O signals for connection by ECs and TSVs, respectively. Low current signals that are not critical (not sensitive to path length and interference) could be included in the second group, for connection by TSVs. Similarly, high-speed (critical) signals requiring comparatively higher current could included in the first group, for connection by ECs. Still other factors than maximum expected current, signal transmission speed, and sensitivity to noise and interference of a signal can additionally be considered in the process of identifying which signals are most appropriately connected by ECs and which are to be connected by TSVs. The specific processes and calculations described above are not intended to be limiting, but are offered by way of example as one way of determining the spacing, width, depth (thickness) and quantity of ECs on any IC chip. The loop is repeated until an entire stack is designed according to the above process and the process then branches to step 521.

In step 521, the IC chips of steps 501-517 are fabricated first as wafers, incorporating ECs for connection of the first group of I/O signals and TSVs for the remaining I/O signals. Fabrication includes intra-chip transistor level structures, traces, and areas of traces aligned for contact with TSVs and ECs, which are sometimes also referred to as chip I/O terminals or die terminals, and TSV and EC structures for external connections. Chip fabrication may include inventive methods 700, 800, 900 described hereinbelow, as well as processes already known in the art, such as the ChipScale™ process (id.). The individual IC chips are manufactured according to the specifications and features determined in prior steps of the process 500. The circuit layouts generated in step 515 for the chips of the stack can be applied to wafers in several alternative ways known in the art. In one embodiment, the same semiconductor wafer fabrication processes are used for all chips of the stack to fabricate the circuits and traces comprising their active layers; in this case, for example, one chip of each stack level can be laid out on the wafer adjacent to each other in groups, and then singulated first into wafer portions, each including all chips of the stack, and then further singulated into individual chips of the stack. This alternative can be advantageous if the desired manufacturing volume is small, for example, during development of a product. In an alternate embodiment, the chips of each stack level are fabricated on a separate wafer; in this case, the wafer fabrication process, and chip size, can be different according to stack level, and further, wafer level packaging can be used to form the stack, rather than packaging of individual (singulated) chips. The stack of IC chips produced therefrom may incorporate any of the features described throughout this disclosure and illustrated in FIGS. 2A-8, as well as any methods and structures known in the prior art.

In step 523, the chips are assembled into a stack, as described hereinabove with reference to FIGS. 2A-4B, and alternatively, methods known in the art which are suitable for use with TSVs and ECs can be used to assemble the stack.

### Dual Interconnection of a Single Chip to a Substrate:

The advantages of dual interconnection described hereinabove with reference to a stack of chips apply also to connecting a single chip to a substrate, in applications wherein it is desirable to mount the chip face-up. In this case, the number of chips to be stacked in step 501 of the process 500 of FIG. 9 is one (1), and there is just one pass through the steps 501-517. Only the “first” chip is fabricated in step 521 and assembled (attached and connected) in step 523 to a substrate. An example of a chip and a substrate incorporating dual interconnection, according to an embodiment of the invention, is illustrated in FIG. 10. The figure depicts a “first” chip 610 (which is also the “top” chip) mounted face-up on a substrate 620, in fragmentary cross-sectional view. An I/O terminal 611 that is a portion of a trace 612 on the active (top) surface 613 of chip 610 is connected by gull lead EC 614 (also referred to as a GEC) to trace 621 on the substrate 620. The GEC 614 has an upper tab portion 615 on the top surface of the chip and a lower tab portion 616 extending distally from the sidewall 617 of the chip, with a bottom contact surface 618 on its underside. Another I/O terminal 619 of the chip 610 is connected by TSV 630 to trace 622 on the substrate 620. The GEC 614 and TSV 630 are separated and electrically insulated from the material of the chip by an intervening layer of electrically insulating material 632, such as silicon dioxide, another oxide, a nitride, or a polymer, as described hereinabove with reference to FIGS. 2A-2C. The bottom contact surface 618 of GEC 614 (as well as the bottom contact surface 631 of TSV 630) protrudes a distance 624 below the rear surface 634 of the chip 610, thereby providing, in some applications, space for adhesive, and the benefit of stress relief, especially if the protrusion distance is greater than the thickness of the GEC, such as by a factor of three. Although one TSV and one EC are shown in FIG. 10, for purposes of simplicity in describing the structure in this embodiment, according to the method 500 of FIG. 9, the power and ground signals are connected by ECs, and high-speed signals are connected by TSVs, to the substrate. The CS signal, also referred to as the chip enable signal, can be connected by an EC in order to minimize the number of TSVs in the active area of the chip. Alternatively, the CS signal can be connected by a TSV, as the considerations relating to pass-through CS signals described hereinabove are not relevant in this one-chip embodiment.

Wafer Level Method of Fabricating a Stacked Chip Module with Dual Interconnections:

In a wafer level packaging process, for example, the chips of the stack are assembled, attached, and bonded in groups, including a plurality of chips of a given stack level, and subsequently singulated into stacked chips. Entire wafers, each including a plurality of chips of a stack level, may be used in the wafer level process, or alternatively, portions of wafers can be used, that have a sufficient number of chips to result in economy of scale in wafer level packaging. An entire wafer or such portion of a wafer is both referred to herein as “wafer”, for brevity. FIG. 11 depicts a sequence of steps 660 that illustrates, by way of example, a wafer level packaging process for manufacturing a semiconductor module including dual interconnection of a stack of IC chips by ECs and TSVs, according to features described above. It is assumed that the wafers were designed and fabricated according to the steps 501-521 described hereinabove with reference to FIG. 9. The process of FIG. 11 is expressed in terms of embodiments wherein multiple chips within a wafer are all identical copies of a chip directed to a particular stack level as described in step 503 of FIG. 9 (i.e., all the chips within a wafer are designated for assembly at the same level or position in their respective stacks). The term “top-chip wafer” therefore refers to a wafer comprising the IC chips designated for the top level in their respective stacks. The process is described as progressing downward one stack level at a time. The reference to the “next” wafer therefore refers to the wafer comprising identical chips designated for identical position in their respective stacks, and one level lower than the chips fabricated from the immediately preceding wafer. The term “first chip wafer” refers to the wafer from which the chips at the “lowest” stack level are fabricated, e.g., the chip adjacent a substrate layer.

The process 660 starts in step 661, with selection of the top-chip wafer (or portion of wafer). In support step 663, a plate or other suitable support layer is attached to the circuit side of the top-chip wafer to convey sufficient rigidity and strength for subsequent processing.

In thinning step 665, the selected wafer, with structures attached to its top side in prior steps, is thinned from the back side to a thickness suitable for the next step 667.

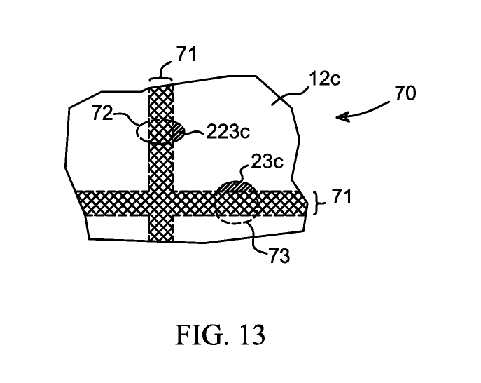

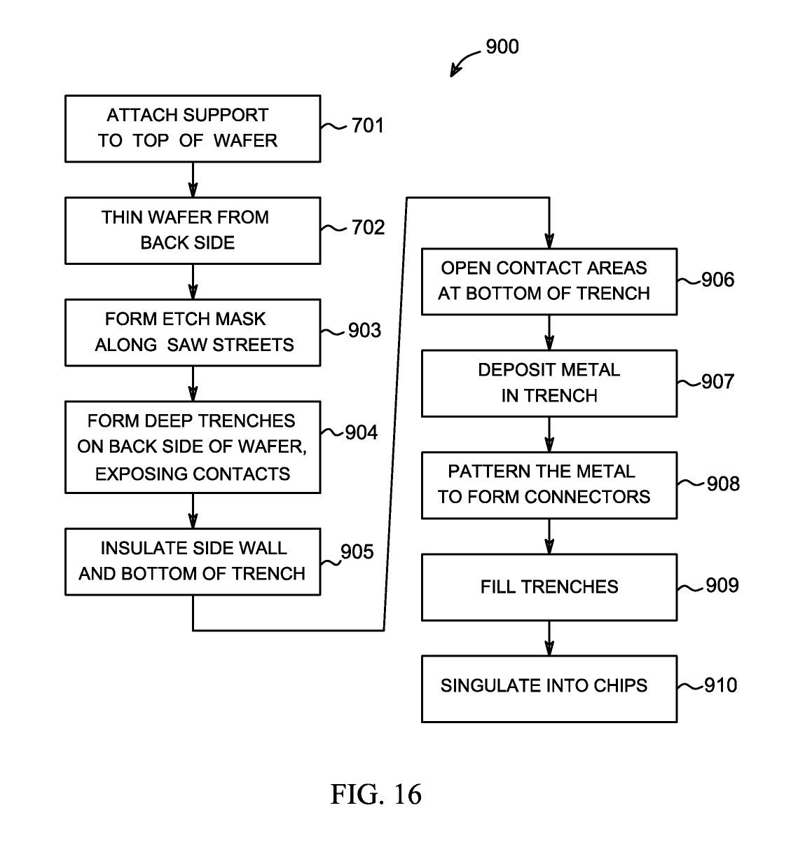

In connector forming step 667, EECs are formed by a back side trench process 900, described hereinbelow with reference to FIG. 16, and at the same time TSV connectors are formed, as described hereinbelow. Alternatively, EECs and TSV connectors can be formed by the process 700 described with reference to FIG. 13.

In branch step 669, if the currently selected wafer is not the first-chip wafer (i.e., the wafer comprising IC chips designated for the bottom of their respective stacks, nearest the substrate, memory controller, or other electrical structure), the process continues to selection step 671, wherein the wafer holding chips of the next stack level is selected.

In stacking step 673, the back contact surfaces of the EECs and TSVs formed in step 667, which are located on the bottom of the stack of wafers formed thus far in the process, are bonded to respective contact areas, also called terminals, on the circuit side of the selected wafer, by techniques described hereinabove and with reference to FIGS. 2A-4B. The process then loops back to the thinning step 605 and continues again through steps 665-669.

If in branch step 669 the currently selected wafer is the first-chip wafer, then the process branches to singulating step 675, wherein the stacked wafer is singulated into stacked chips, and the wafer level packaging process ends.

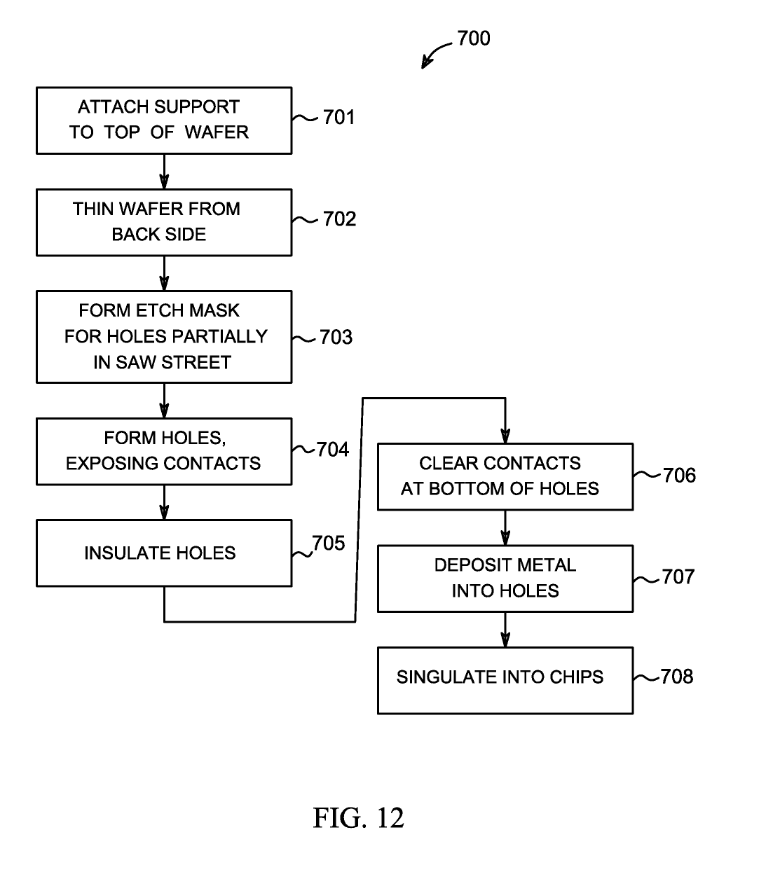

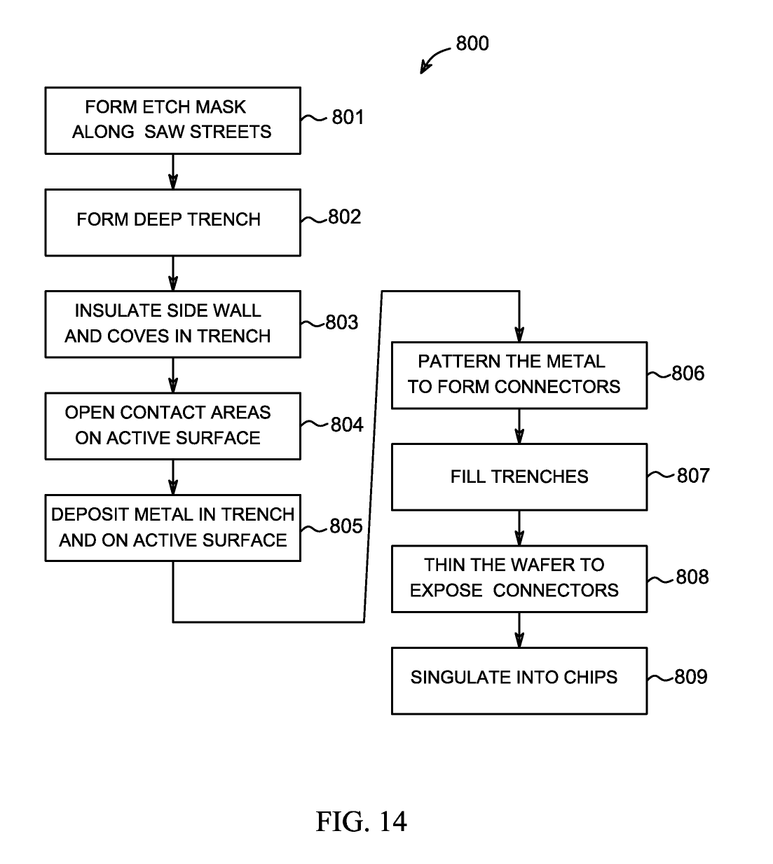

The wafer level packaging process for manufacturing a semiconductor module incorporating dual interconnection by ECs and TSVs, described hereinabove, uses back side EC and TSV forming processes 900 and 700 (of FIGS. 16 and 12), which are described hereinbelow. In an alternate embodiment, the wafer level packaging process can use the top side EC and TSV forming process 800 described hereinbelow with reference to FIG. 14. In the alternate embodiment, the order of the wafer thinning and connector forming (steps 665 and 667 of FIG. 11) is reversed, so that edge connectors and TSV connectors are formed first, incorporating elements of the process 800, and the wafer is thinned in the next step, with the process remaining otherwise substantially the same as illustrated in FIG. 11.

Specific details of the embodiment described in FIG. 11 envision whole (unsingulated) wafers stacked and assembled prior to singulation into individual chip-stacks. However, this sequence is not essential to the application of the principles described in FIG. 11. In an alternative embodiment, singulation of a wafer into individual chips may precede stack assembly.

### First Method to Fabricate the EEC (Hole Partly in Saw Street):

A process for formation of an EEC, according to an embodiment of the method of the present invention, is illustrated in FIG. 12, which shows a sequence 700 of steps (also referred to as process or method) in flow diagram form. The input material to the method 700 includes a processed semiconductor wafer containing a plurality of completed integrated circuits (ICs) spaced by saw streets, along which the IC chips will be separated (singulated, diced) from the wafer. The process can be clearly understood with reference also to FIG. 13, which shows a top plan view of a portion of a wafer 70 including saw streets 71 and corner portions of four IC chips, including IC chip 12c, which is also shown in FIGS. 2A-2C. In the first (support) step 701 of the sequence of steps 700, a support layer or plate is attached to the top (active) surface to mechanically strengthen the wafer during and after it is thinned. The support plate can be removed before or after singulation of the wafer into chips, as desired according to the application.

In thinning step 702, material is removed from the rear (back, bottom) side of the wafer to reduce the wafer thickness to a value suitable for forming holes through or almost through the wafer. In step 703, a mask is formed on the back side of the wafer for hole formation by a known process. In processes utilizing etching, this mask formation step 703 can include the sub-steps of depositing a mask layer on the back surface, and patterning the mask to expose select areas of the back surface conforming to die terminal positions in which through silicon via holes, and columns of conductive material deposited in the holes, intersect the active surface, for electrical contact to (the underside of) the die terminals. In processes utilizing laser ablation, the masking step 703 can include the steps of appropriate indexing, programming of the mechanical stepping, and beam shaping.

In step 704, a plurality of holes 72, 73 are formed, starting from the back side and extending nearly through the wafer. The last formed portion of a hole, nearest the top side of the wafer, may also be referred to as the “bottom” of the hole. The holes are suitably disposed straddling the saw street at the edges of the chips, as shown in phantom in FIG. 13, to illustrate that the holes being formed from the rear surface do not penetrate completely through the upper (active) surface of the IC chip. The cross-sectional view of hole 72 includes a region extending beyond the saw street 71 and into IC chip 12c, thereby identifying (in plan view) a recess 223c in the sidewall of IC chip 12c, which, when filled with a conductive material, will form EEC 22. In a similar manner, the cross-sectional area of hole 73 includes the cross-sectional area of recess 23c, which, when filled with a conductive material, will form another EEC 20c. When an EEC is designed to extend downward from a circuit trace, at a die terminal location, the hole formation process can be programmed to terminate prior to penetrating the metal layer (circuit trace). As the hole reaches the underside of the metal layer (from which circuit traces, such as 16, 16b, 17c of FIGS. 2A, 2B are formed), the depth of the hole can be controlled to expose the underside of the metal layer to ensure good electrical contact between the EEC and the circuit trace. In case of etching, techniques such as chemical selectivity, whereby a wafer material is removed faster than a metal, can be utilized to control the depth of the hole. In the case of laser ablation, differential optical reflectivity can be utilized to terminate penetration when the inner surface of the metal layer is reached.

In step 705, an insulating layer 21 is formed on the sidewalls inside the holes to avoid unintended electrical contact to elements of the active layer and substrate, by a suitable technique known in the art, such as thermal oxidation or sputtering of an oxide or other insulating material. Those skilled in the art will appreciate that the process described in FIG. 12, in conjunction with forming EECs, also can be used in forming, insulating and filling holes used for TSVs.

During step 705, some of the sputtered insulation material may accumulate on the underside of the contact trace. To ensure optimal electrical continuity between the EEC and the contact trace, this insulating material must be selectively removed from the contact area prior to the step of electroplating. In step 706, therefore, contact areas identified for electroplating are cleaned by removing any insulating material that was dispersed onto their surfaces during the insulation step, by a known process such as disclosed by Barnes, et al. (U.S. Pat. No. 5,505,816).

In step 707, a starting (seed) layer for electroplating is first applied by a known technique, such as sputtering metal on the insulating layer on the sidewalls. After the seed layer is formed, a process such as electroplating is used to complete the formation of the metal columns within the holes. It can readily be appreciated that the electroplating process occurs on the underside of the contact trace and the sidewall of a hole, progressively filling a hole inward. As the diameter of the hole decreases, the ingress of metal into the hole may be progressively impeded. EECs, according to the present embodiment (and TSV connectors), therefore, are often formed with a hollow core. The minimal cross-sectional area of the tubular metal wall of an EEC or TSV is typically dictated by the anticipated current loads through the connector.

In step 708, the wafers are singulated into chips by removing the material in the saw streets 71 through any number of known techniques, such as mechanically sawing through the wafer along the saw streets, water jet, laser ablation, or chemical sawing.

Prior to singulation of a wafer into individual IC chips, EECs are formed in substantially the same manner as TSVs, and therefore exhibit the same “metal tube” cross-section as described above in conjunction with TSVs. In the singulation process, the material within the saw streets 71, including the portion of the metal columns within the saw streets 71, is disintegrated. After singulation, the cross-sectional area (in the wafer plane) of the EECs is coextensive with the silhouetted portions 223c and 23c of holes 72 and 73, respectively, of FIG. 13.

The singulation process thereby exposes the sidewalls of an IC chip, including the outer surfaces of the conductive columns that form the EECs.

Referring again to FIGS. 2A-2C, EECs 20, 20b, 20c, and 22 are shown to be slightly conical in shape, reflecting the shape produced by the hole formation process. However, the shape can be tailored to some extent, and the hole may therefore exhibit a more cylindrical shape, if desired. The size (diameter) and shape of a hole in the wafer plane may be varied according to design preferences. The geometry of a hole can therefore be selected to achieve a desired shape of an EEC formed therefrom. Throughout this disclosure, therefore, specific examples depicting a conical, cylindrical, or other geometric shapes or sections, are so limited for economy of expression, and should not be construed as limiting the appended claims, which fully envision TSVs and EECs exhibiting alternative geometric shapes and sections.

### Modified First Method to Fabricate the EEC (or TSV):

The embodiment depicted in FIGS. 2A-2C, 12, and a process for fabricating that embodiment, such as the method disclosed in FIG. 12, were directed to an embodiment in which material is removed from the silicon wafer beginning from the “bottom” (opposite the active surface), and wherein that process of etching or removal of material ceased as the hole reached a depth extending to a circuit trace situated on the active surface. Embodiments are also envisioned wherein a hole for a TSV or an EEC extends completely through the wafer (and chip), from the active surface to the rear surface. A hole completely traversing an IC wafer is preferably filled with metal, according to the same process described above. A circuit trace, subsequently, may be formed on one of the surfaces of the wafer to electrically couple with the TSV or EEC produced by the plated through hole.

### Second Method to Fabricate the EEC (Trench Along Saw Street, on Top of Wafer):

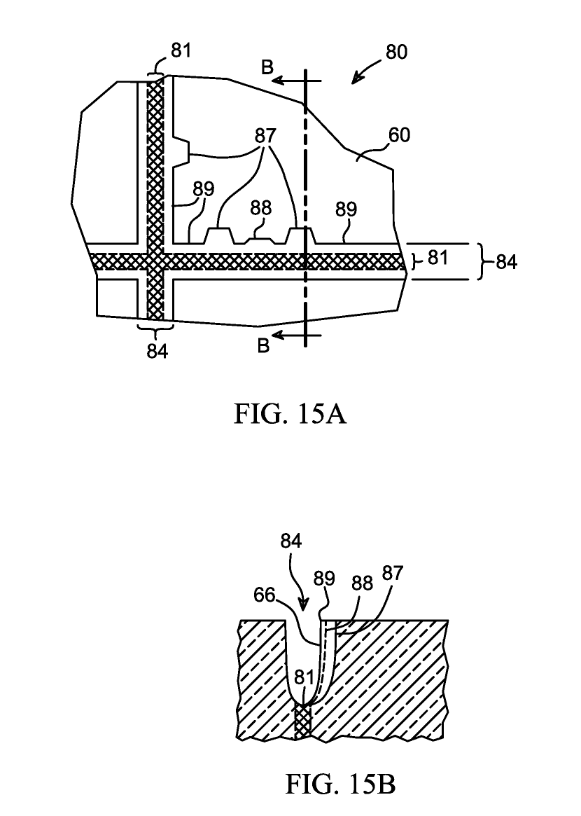

FIG. 14 is directed to an alternative embodiment of a process for formation of an EEC or GEC wherein removal of material begins at the active surface (top side) of the wafer. The process includes a sequence 800 of steps (also referred to as method), depicted in flow diagram form in FIG. 14. The input material to the method 800 includes a semiconductor wafer containing a plurality of completed IC chips spaced by chip separation bands which include saw streets. The process can be more clearly understood with reference also to FIG. 15A, which shows a top plan view of a portion of a wafer 80 including saw streets 81 and corner portions of four IC chips, including IC chip 60, which is also shown in FIG. 4A. The process is described, at least in part, in terms of elements depicted in FIGS. 15A, 15B, and 4A. A first removal of material forms trenches 84 (also called grooves) aligned with saw streets 81. FIG. 15A depicts a top plan view of a wafer section showing intersecting trenches 84 and saw streets 81 separating four separate chips, including chip 60. Within chip 60, recesses 87, 88 depict the cross-sectional geometric shape of an alternative embodiment of an EEC. Trenches 84 are formed along saw streets 81, and recesses 87, 88 are formed in the edge of the chip, which also includes straight, not recessed portions 89 of the edge and sidewall 66. FIG. 15B illustrates an example of the profile of a trench 84 in cross-sectional view through the wafer, taken along the line B - B shown in FIG. 15A. In this embodiment, the saw street 81 is narrower than the trench 84, so that the sidewall 66 of the trench will form the edge of the chip 60, as shown in the example of FIGS. 15A, 15B, 4A. Alternatively, the saw street can be wider, extending, for example, to the edge 89 and sidewall 66 of the trench 84, or slightly beyond 89 but not as far as to include the entire recesses 87, 88, and in this case the sidewalls of the chip will be formed by removal of material in the saw street, in the process of singulating the wafer into chips, as illustrated, for example, in FIG. 2D. It should be noted that in the embodiment of FIGS. 2D, 4A, 4B, 14, 15A, 15B, a recess does not necessarily extend across the saw street, as in the embodiment described in conjunction with FIG. 13. With reference to FIG. 4A, embedded ECs 62, 63 that in the example of chip 60 also have gull leads, are formed within the recessed areas through a process of plating a conductive material onto the sidewalls of a recess, according to the process described in FIG. 14 discussed herewith. It is understood that in the process, conductive material will also be deposited on exposed surfaces of the trench, on the sidewall portions indicated by the projected chip edge 89 that are not recessed, and at the bottom of the trench in the saw street. Thus, in addition to the EECs 62, 63 in the recesses 87, 88, ECs 64 that are not embedded can be formed on the straight sidewall areas 89 by suitable masking and selective removal of conductive material.

With reference to FIG. 14, in a first step 801, an etch mask is applied to the surface of the wafer according to a pattern configured to expose predetermined areas on the active surface which have been designated for etching, including the locations at which the respective trenches and recesses will be formed. The remaining surface areas of the chip are covered by the mask layer. In step 802, a deep trench is formed in the exposed area, extending, for example, 100 to 150 micrometers, down from the active surface into the wafer, but not completely through the bottom surface of the wafer. The position of the sidewalls of each trench is determined by the mask pattern. The sidewalls of each trench include sidewalls of the recesses 87, 88 formed in the structure of a chip, such as chip 60, and intervening straight sidewall portions 89, which will define the edge of the chip (when the saw street does not extend to the sidewall of the trench). The recesses can have different shapes, as illustrated by the deep recesses 87 and shallow recess 88 depicted in FIGS. 15A, 4A. In step 803, an insulating layer is formed on the sidewalls of the trench, including the recesses, to prevent unintended electrical contact with any signal paths terminating at the walls of the trench. The insulating layer may be formed by any suitable technique known in the art, including but not limited to, thermal oxidation or sputtering of an insulating material. The wafer 80 has traces (not shown in FIGS. 2D, 4A, 4B, 15A, 15B, but illustrated as elements 16, 17 and 18 in FIGS. 2A and 2B) on its active surface, and extending to the edge of the trench, also referred to as I/O terminals, contact terminals, or die terminals, which are suitably aligned for electrical contact to the ECs that will be formed on the sidewall of the trench (and chip), to overlap with contact areas of the traces. In step 804, contact areas for electroplating are opened (cleared of insulating material and etch mask material) on the traces, on the active surface near the edge of the trench. In step 805, a starting (seed) layer is first applied by a known technique such as sputtering of metal, and then a thicker metal layer is deposited on the sidewall and in the recesses in the trench, on the bottom of the trench, and on the contact areas of the chip on the active surface of the wafer, by a suitable method, such as electroplating. The surface shape of a recess can be adapted to enhance the plating thickness in the recess, compared to the thickness of plated metal on the intervening straight portions of the sidewall, by techniques known in the art, such as superfilling. In step 806 of FIG. 14, which references elements depicted in FIGS. 15A, 15B and 4A, the conductive material is selectively removed from the active surface, the sidewall, and the bottom of the trench, so as to electrically isolate a plurality of conductive strips, thus forming ECs which can include EECs, GECs, conventional EWCs, and ECs with combined features of these, according to the shapes of the conductive strips or regions formed by the material removal process. As shown in FIGS. 2D, 4A, 4B, multiple adjacent strips are fabricated, which can exhibit a uniform spacing (pad pitch) 34 along the edge, as illustrated in FIG. 2D. (Uniform pitch may be understood as a plurality of ECs depicting equal width, equal spacing between the ECs, or both of these features. It should be further noted, in conjunction with FIGS. 4A, 4B, that adjacent EECs can exhibit a uniform spacing or pad pitch even when the depth and/or cross-sectional area of those EECs are distinct.) The strips in the deep recesses 87 of the sidewall form EECs 62 that have a larger cross-sectional area relative to the other EECs of FIG. 4A; the strips in the shallow recesses 88 form EECs 63 that have a smaller cross-sectional area than EEC 62; and the strips on the straight portions 89 form ECs 64 disposed on the sidewall 66 (similarly to conventional EWCs, such as the ChipScale™ EWC disclosed by Chen (id.) but also including inventive gull lead features that are not a feature of ChipScale™ EWCs) that in this embodiment can have a still smaller cross-sectional area. The current-carrying capacity and impedance of an EEC depends on the cross-sectional area, and can thus be tailored for the application, while keeping a uniform pad pitch on the chip, which is generally desirable for assembly.

After patterning the connectors, the trenches are filled, in filling step 807, with a suitable insulating material that can protect the connectors and provide additional mechanical integrity to the wafer prior to singulation. In an alternate embodiment, the trench filling step 807 can be omitted.

In thinning step 808, the wafer is thinned from the back side of the wafer up to approximately the bottom of the trench, so as to expose the underside of the conductive strips. The layer of insulating material between the wafer and the conductive strip can be removed from the underside of the conductive material to expose the bottom contact surface, along with the wafer material, or by a separate removal step. A selective thinning technique can be used, whereby the wafer material is removed faster than the insulating material, or faster than the conductive material of the ECs. Known selective material removal techniques can be used, such as selective chemical etching, that removes silicon or other semiconductor material faster than it removes an oxide, or a metal; or differential reflectivity in laser ablation, whereby laser energy is absorbed well by the semiconductor material, and by the insulating material, thereby vaporizing it, but is reflected and not absorbed well by a metal, thus leaving the metal undisturbed. Selective thinning of the wafer can continue slightly beyond the point of exposure of the conductive strip, so that the underside of the conductive strips or ECs will be left protruding slightly beyond the back surface of the chip. In an embodiment, therefore, the protrusion distance can be greater than the conductive material thickness at the bottom of the trench.

In an embodiment having no conductive strips bridging the saw street and no trench filling step 807, singulation into chips occurs at the end of step 808.

In embodiments wherein the trench is filled with insulating material, or thinning of the wafer exposes the underside of the conductive strips but leaves some material at the bottom of the trench, which can include conductive material and wafer material, all such material within the saw street 81 (FIGS. 15A, 15B) is removed in the last step 809, thereby singulating the wafer into chips.

Referring again to FIGS. 4A and 4B, by selectively leaving extensions 69 of the conductive strips on the bottom of the trench during patterning (in step 806) and singulation (in step 809), lower tab portions 69 of the ECs are formed that extend distally from the side of the chip 60 after singulation, thus forming GECs. Another embodiment, shown in FIG. 10 and described in greater detail hereinabove, depicts a GEC 614 with lower tab portion 616 extending distally from the sidewall 617 and protruding a distance 624 beyond the back surface 634 of the chip. Further, the lower tab portion 616 and contact surface 618 are located outside the perimeter of the chip, thereby allowing inspection of the bond and access from above, after the chip is attached to the substrate. Depending on the application, this architecture may facilitate a more convenient attachment and connection to an adjacent chip or substrate, as well as a faster and more accurate inspection of the connections. Depending on the choice of the dimensions, such extensions 69, 616, sometimes also called tabs, can also provide the benefit of stress relief of differences in thermal expansion of a chip and a substrate by allowing some flexure of the tab.

Those skilled in the art will appreciate that the process 800 described in FIG. 14 in conjunction with forming ECs (including EECs and GECs) also can be used in forming TSVs, beginning with material removal from the active surface of the wafer. In contradistinction to the FIG. 12 method 700 to fabricate the EEC and TSV, it is not necessary in the current (FIG. 14) method 800 to clear insulating material from the bottom of a hole, as the contact area for electroplating is opened on top of the wafer. With reference to FIG. 10 and chip 610 depicted therein, insulating material 632 is removed from the bottom contact surfaces 631 and 618 of TSV 630 and EC 614, respectively, as part of the thinning step 808. The formation of EC structures depicted in FIGS. 4A, 4B can be accomplished by deposition and selective removal of conductive material, as disclosed in steps 805 and 806 of FIG. 14. The EEC embodiment depicted in FIG. 2D, which is similar to the embodiments illustrated in FIGS. 4A and 4B, but without the lower tabs 69, can be produced in the singulation step 809 described hereinabove, by adapting the saw street to be at least as wide as the trench.

### Third Method to Fabricate the EEC (Trench Along Saw Street, on Bottom of Wafer):

FIG. 16 describes an alternative embodiment of a process for fabricating EECs, shown in flow diagram form, including a sequence of steps 900. In method 900, trenches are formed starting from the rear (back, bottom) side of the wafer, and ending near the active surface. The process of FIG. 16 includes some common features with the processes 700 and 800, described in conjunction with FIGS. 12 and 14. The first two steps of the FIG. 16 method are substantially similar to the steps 701 and 702 of the FIG. 12 method, as described hereinabove, and are identified by same reference numerals. In mask forming step 903, the rear surface is masked according to a pattern that will form trenches, including recesses. The trenches are formed along, and coinciding with, chip separation bands, which include saw streets. The recesses are aligned to make contact with the underside of respective traces on the active surface that comprise the die terminals. Step 903 is substantially similar to step 801 of FIG. 14, except for the surface, which is masked.

In step 904, the trenches are formed at the back side of the wafer, by methods known in the art, such as chemical etching, laser ablation, etc., as in step 802 of FIG. 14, with an important difference. In step 904, a selective material removal technique is employed in at least a latter portion of the trench forming process, to control the depth of the trench so as to expose the underside of the contact metal layer of the die terminals at the active surface, to which the EC will make electrical contact. The trench forming process can be programmed to terminate prior to penetrating the contact metal layer of the die terminals. The last formed portion of a trench, nearest the top side of the wafer, may also be referred to as the “bottom” of the trench.

In step 905, an insulating layer is formed on the sidewalls of the trench, including the recesses, to prevent unintended electrical contact with any signal paths terminating at the walls of the trench. The insulating layer may be formed by any suitable technique known in the art, including but not limited to, thermal oxidation or sputtering of an insulating material, as in step 803. The technique employed may result in insulating the underside of the contact metal layer at the bottom of the trench. Additionally, the back or bottom surface of the wafer is insulated. Insulated standoffs can also be formed on the back surface, as known in the ChipScale™ process, disclosed by Chen (id.) and Richards (id.).

In step 906, contact areas on the underside of the traces are opened (cleared or cleaned of insulating material) by suitable masking and insulating layer removal processes known in the art. In step 907, metal is deposited on the sidewalls and in the recesses, and on exposed contact areas of the underside of conductive traces disposed along the active surface, at the bottom of the trench, and also on the back or bottom surface of the wafer, according to the ChipScale™ process (id.), including on any standoff structures that may be present, generally as in step 805 of the FIG. 14 method described hereinabove.

Those skilled in the art will recognize that the steps of the process 900—step 907 described hereinabove in conjunction with forming EECs, can be adapted to form also TSV connectors at the same time, by suitably modifying the mask pattern in step 903 to form also holes for TSVs.

In step 908, the metal is patterned to form the EECs, as in step 806, and also to form traces and contact areas on the back surface of the wafer, according to the application. In step 909, the trenches can be filled generally as in step 807, however, in this embodiment the trenches are at the rear of the wafer, and in a face-up stacking configuration, contact areas on the rear surface are opened or kept free of the trench filling insulating material. In the final step 910 of the method of this embodiment, the wafer is singulated into chips by removing the material in the saw street, as described with reference to step 809.

While the invention has been described hereinabove with respect to interconnections between (integrated) circuits and traces on the active surface of a semiconductor chip, it will be apparent to those skilled in the art that the structure and principles of the invention can be applied with equal effect to chips containing also various types of electromagnetic wave guiding paths or a combination of such circuits and wave guiding paths. It will be further apparent that the invention can also be applied to composite chips wherein the circuits and traces can be in a first layer constructed of one material, for example, a semiconductor material, or a plurality of such layers; and another layer, constructed of another material and attached to the first layer, can serve as the portion that provides mechanical strength to the chip, or that serves other purposes for the chip. In yet an alternate embodiment, the inventive dual interconnection with ECs and TSVs can provide interconnections between chips in a stack of chips providing the same function as a multichip module or circuit board of current art, other than a memory module, but with shorter interconnection paths and accordingly shorter signal delay times than the current-art multichip module or circuit board.

1. Apparatus comprising:
an integrated circuit die having a topside and a bottom side;
an integrated circuit formed in the topside of said die;
a plurality of topside contact terminals;
said integrated circuit having two groups of signals, a first group consisting of slow speed signals and a second group consisting of high-speed signals;
the integrated circuit having means for connecting the slow speed signals to a first group of topside contact terminals;
the integrated circuit having means for connecting the high speed signals to a second group of topside contact terminals;
a plurality of edge electrical connectors connected to said first group of topside contact terminals;
a plurality of through-hole vias connected to said second group of topside contact terminals; and
a plurality of via electrical connectors connected to said second group of topside contact terminals through said through-hole vias;
whereby the high-speed signals are connected to the via electrical connectors and the slow speed signals are connected to the edge electrical connectors.

2. Apparatus according to claim 1, wherein said slow speed signals are selected from the group consisting of power, ground, and chip select.

3. Apparatus according to claim 1, further including a plurality of contacts formed on the bottom side of the die wherein said via electrical connectors are connected to a least a subset of said bottom side contacts.

4. Apparatus according to claim 1, further including a plurality of contacts formed on the bottom side of the die wherein said edge electrical connectors are connected to a least a subset of said bottom side contacts.

5. Apparatus according to claim 1, wherein said die has one or more recesses formed on the side of said die and at least one of said edge connectors is formed in said at least one recess.

6. Apparatus according to claim 5, wherein the at least one of said edge connectors formed in said at least one recess is connected to supply power to said integrated circuit.

7-29. (canceled)
